(19) United States
(12) Patent Application Publication
(10) Pub. No.: US 2026/0002970 A1
(43) Pub. Date: Jan. 1, 2026

(54) Wireless Environment Estimation System and Wireless Environment Estimation Method

(71) Applicant: Hitachi, Ltd., Tokyo (JP)

(72) Inventors: Ken TAKEI, Tokyo (JP); Masami OHNISHI, Tokyo (JP); Yuichi IGARASHI, Tokyo (JP)

(21) Appl. No.: 19/196,133

(22) Filed: May 1, 2025

(30) Foreign Application Priority Data
Jun. 27, 2024 (JP) 2024-104318

(51) Int. Cl. G01R 29/08

(52) U.S. Cl. CPC G01R 29/0871; G01R 29/0892

(57) ABSTRACT

Provided is a wireless environment estimation system that stores stationary structure data including structure data of a stationary structure in a wireless communication area, moving object data including structure data of a moving object in the wireless communication area, and observation region data related to an observation region of an electromagnetic field, uses the stationary structure data and the observation region data to generate a first electromagnetic field analysis model for analyzing an electromagnetic wave reflected by the stationary structure in the observation region, sets a primary wave source at a position of a wireless station, generates a secondary transmission point from an electromagnetic field that is obtained by calculation using the first electromagnetic field analysis model and that reaches the observation region, uses the moving object data and the observation region data to generate a second electromagnetic field analysis model for analyzing an electromagnetic wave emitted from the secondary transmission point, and uses the second electromagnetic field analysis model to calculate an electromagnetic field caused by an electromagnetic wave emitted in a direction opposite to that of an electromagnetic wave reaching the secondary transmission point.

### CLAIM OF PRIORITY

The present application claims priority from Japanese patent application JP 2024-104318 filed on Jun. 27, 2024, the content of which is hereby incorporated by reference into this application.

### BACKGROUND OF THE INVENTION

### 1. Field of the Invention

The present invention relates to a wireless environment estimation system, and more particularly to a technique for estimating a wireless environment in a wireless communication service area to implement a wireless digital twin that reproduces the wireless environment in the service area.

### 2. Description of Related Art

A wireless system is used to communicate information to and from a remote object, and also to monitor and control the remote object by transmitting and receiving information using electromagnetic waves. The electromagnetic waves serving as a communication medium are emitted into a space from a transmitter and then reach a receiver either directly or after being reflected and diffracted by an electromagnetic wave scatterer. Therefore, the communication quality of wireless communication using the electromagnetic waves is affected by the position and the posture of the scatterer surrounding the transmitter and the receiver. The changes in relative position and relative posture with respect to the electromagnetic wave scatterer caused by the movement change the wireless communication characteristics.

When there is an electromagnetic wave scattered around the transmitter or the receiver, the electromagnetic field distribution can be analytically or numerically calculated by an electromagnetic field analysis using a Maxwell equation by using the transmitter as a transmission point, the receiver as a reception point, and the electromagnetic wave scatterer as an object having a dielectric constant and a magnetic permeability. In general, the difficulty of the electromagnetic field analysis, that is, the calculation time, increases exponentially due to an increase in the number and complexity of the shape of the electromagnetic wave scatterers around the transmitter or the receiver. However, with the rapid progress of computer resources in recent years, in most wireless systems currently in operation, the electromagnetic field distribution in the same wireless system can be calculated in less than a minute.

Under such circumstances, a technique called wireless digital twin has been proposed, which uses the electromagnetic field distribution obtained through the electromagnetic field analysis using the computer resources to reproduce in cyberspace the behavior of the wireless systems present in actual space and estimate the communication characteristics of the wireless systems in the actual space. By using data on the positions of the transmitter and the receiver in a wireless communication area and data on the position, the posture, the structure, and the electrical characteristics of the electromagnetic wave scatterer around the transmitter and the receiver, the electromagnetic field distributions in all locations in the wireless communication service area is calculated without actual measurement, and the wireless communication characteristics in the same area can be reproduced in the cyberspace based on the calculation result. When the wireless digital twin is used, the wireless communication characteristics after the position and the posture of the electromagnetic wave scatterer in the actual space is changed can be predicted.

The following prior art is included as background art in the technical field. PTL 1 (JP2021-158397A) discloses a control device including a position prediction unit configured to predict a position of a host terminal having a communication function, an information acquisition unit configured to acquire geographic information around the position of the host terminal predicted by the position prediction unit, and a communication control unit configured to control communication between the host terminal and another terminal having the communication function other than the host terminal based on the geographic information.

PTL 2 (JP2023-39929A) discloses a method executed by an in-vehicle computer of an ego vehicle, the method including: sensing a remote vehicle by a sensor set of the ego vehicle to generate sensor data describing a driving behavior of the remote vehicle; comparing the sensor data with a reference set for an abnormal driving behavior; determining that a subset of the reference set is described by the sensor data, the subset satisfying a threshold for early detection of the abnormal driving behavior; and determining that the remote vehicle is involved in the abnormal driving behavior based on the satisfying of the threshold.

### Citation List

### Patent Literature

PTL 1: JP2021-158397A
PTL 2: JP2023-39929A

### SUMMARY OF THE INVENTION

The prior arts described above disclose a technique for monitoring and controlling the operating state of a moving object. Still, both techniques are based on the premise that a wireless communication line for transmitting information for monitoring and control to the moving object is high in quality and stable, not considering a variation in the wireless line required for monitoring and controlling the moving object. When there is a moving object in the wireless communication area, the wireless communication characteristics in the actual space generally change according to the movement speed of the moving object. When the electromagnetic field analysis for the position and the posture of the fixed electromagnetic wave scatterer requires several seconds to several minutes, a delay occurs in the position and the posture of the moving object by the time required for the electromagnetic field analysis, and changes in position and posture of the moving object are not reflected in the wireless digital twin. When the wireless digital twin is used to evaluate the influence on the wireless communication environment caused by the moving object in the wireless system and monitor and control the moving object, it is necessary to speed up the electromagnetic field calculation according to the movement speed of the moving object and generate the wireless digital twin at the most recent time point.

A representative example of the invention disclosed in the present application is as follows. That is, a wireless environment estimation system includes a computer including an arithmetic device configured to execute predetermined processing and a storage device connected to the arithmetic device, the storage device stores stationary structure data including structure data of a stationary structure in a wireless communication area, moving object data including structure data of a moving object in the wireless communication area, and observation region data related to an observation region of an electromagnetic field, and the arithmetic device uses the stationary structure data and the observation region data to generate a first electromagnetic field analysis model for analyzing an electromagnetic wave reflected by the stationary structure in the observation region, sets a primary wave source at a position of a wireless station, generates a secondary transmission point from an electromagnetic field that is obtained by calculation using the first electromagnetic field analysis model and that reaches the observation region, uses the moving object data and the observation region data to generate a second electromagnetic field analysis model for analyzing an electromagnetic wave emitted from the secondary transmission point, and uses the second electromagnetic field analysis model to calculate an electromagnetic field caused by an electromagnetic wave emitted in a direction opposite to that of an electromagnetic wave reaching the secondary transmission point.

According to one aspect of the invention, the communication environment can be estimated in a short time. Problems, configurations, and effects other than those described above will be clarified by the description of the following embodiments.

### BRIEF DESCRIPTION OF THE DRAWINGS

FIG. 1A is a diagram illustrating a wireless digital twin according to Embodiment 1;

FIG. 1B is a diagram illustrating an operation of a wireless environment estimation system according to Embodiment 1;

FIG. 1C is a diagram illustrating an operation of the wireless environment estimation system according to Embodiment 1;

FIG. 1D is a diagram illustrating an operation of the wireless environment estimation system according to Embodiment 1;

FIG. 1E is a diagram illustrating an operation of the wireless environment estimation system according to Embodiment 1;

FIG. 1F is a diagram illustrating an operation of the wireless environment estimation system according to Embodiment 1;

FIG. 1G is a diagram illustrating a configuration example of received segment accumulation data according to Embodiment 1;

FIG. 1H is a diagram illustrating a configuration example of ray payload data according to Embodiment 1;

FIG. 1I is a flowchart of processing executed by the wireless environment estimation system according to Embodiment 1;

FIG. 1J is a diagram illustrating a hardware configuration of the wireless environment estimation system according to Embodiment 1;

FIG. 2A is a diagram illustrating a wireless digital twin according to Embodiment 2;

FIG. 2B is a diagram illustrating the wireless digital twin according to Embodiment 2;

FIG. 2C is a diagram illustrating an operation of a wireless environment estimation system according to Embodiment 2;

FIG. 2D is a diagram illustrating an operation of the wireless environment estimation system according to Embodiment 2;

FIG. 2E is a diagram illustrating an operation of the wireless environment estimation system according to Embodiment 2;

FIG. 2F is a diagram illustrating an operation of the wireless environment estimation system according to Embodiment 2;

FIG. 3A is a diagram illustrating a wireless digital twin according to Embodiment 3;

FIG. 3B is a diagram illustrating the wireless digital twin according to Embodiment 3;

FIG. 3C is a diagram illustrating an operation of a wireless environment estimation system according to Embodiment 3;

FIG. 3D is a diagram illustrating an operation of the wireless environment estimation system according to Embodiment 3;

FIG. 3E is a diagram illustrating an operation of the wireless environment estimation system according to Embodiment 3;

FIG. 3F is a diagram illustrating an operation of the wireless environment estimation system according to Embodiment 3;

FIG. 4A is a diagram illustrating a wireless digital twin according to Embodiment 4;

FIG. 4B is a diagram illustrating an operation of a wireless environment estimation system according to Embodiment 4;

FIG. 4C is a diagram illustrating an operation of the wireless environment estimation system according to Embodiment 4;

FIG. 5A is a diagram illustrating a wireless digital twin according to Embodiment 5;

FIG. 5B is a diagram illustrating the wireless digital twin according to Embodiment 5;

FIG. 5C is a diagram illustrating the wireless digital twin according to Embodiment 5;

FIG. 5D is a diagram illustrating the wireless digital twin according to Embodiment 5;

FIG. 6 is a diagram illustrating a wireless digital twin according to Embodiment 6;

FIG. 7A is a diagram illustrating a configuration of a wireless environment estimation system according to Embodiment 7;

FIG. 7B is a flowchart of processing executed by the wireless environment estimation system according to Embodiment 7;

FIG. 7C is a flowchart of the processing executed by the wireless environment estimation system according to Embodiment 7;

FIG. 8A is a diagram illustrating another configuration of a wireless environment measurement system according to Embodiment 8;

FIG. 8B is a flowchart of processing executed by the wireless environment estimation system according to Embodiment 8;

FIG. 8C is a flowchart of the processing executed by the wireless environment estimation system according to Embodiment 8;

FIG. 9A is a diagram illustrating a display example of a prediction result of an electromagnetic field distribution according to Embodiment 9;

FIG. 9B is a diagram illustrating another display example of the prediction result of the electromagnetic field distribution according to Embodiment 9;

FIG. 10A is a diagram illustrating a configuration example of an operation monitoring control system using a wireless digital twin according to Embodiment 10;

FIG. 10B is a diagram illustrating a currently estimated state of a wireless communication quality of a wireless system grasped by a moving object controlling server according to Embodiment 10;

FIG. 10C is a diagram illustrating a future predicted state of the wireless communication quality of the wireless system that is predicted by the moving object controlling server according to Embodiment 10; and

FIG. 11 is a diagram illustrating another configuration example of an operation monitoring control system using a wireless digital twin according to Embodiment 11.

### DESCRIPTION OF EMBODIMENTS

Hereinafter, embodiments will be described with reference to the drawings.

### Embodiment 1

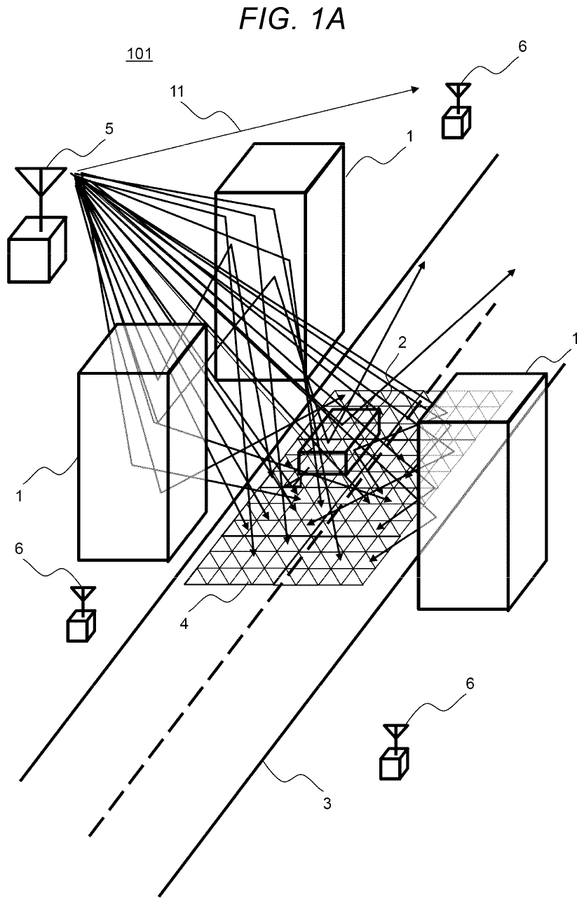

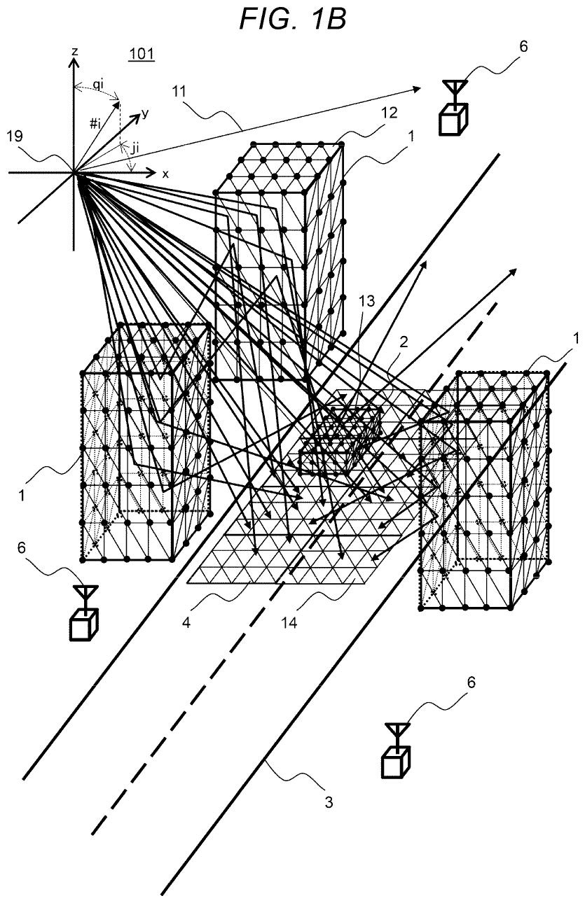

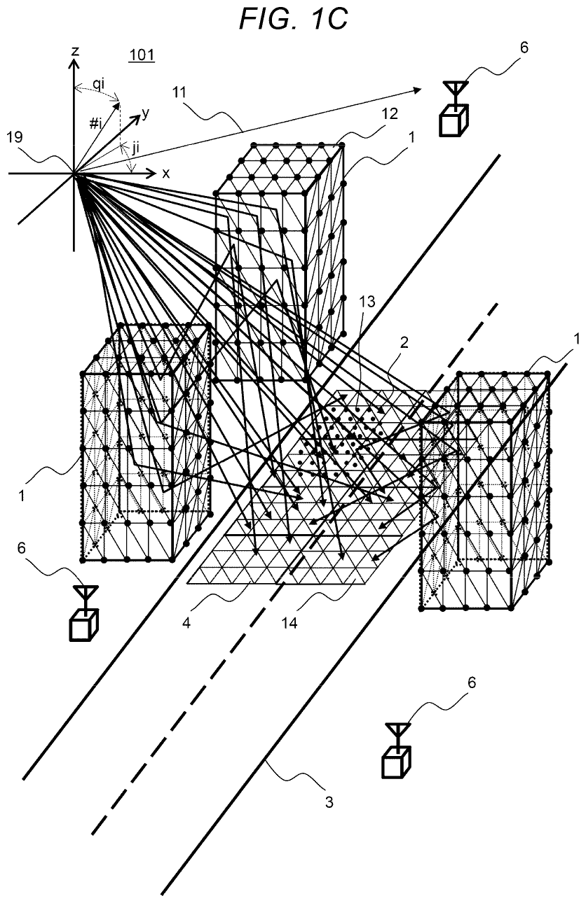

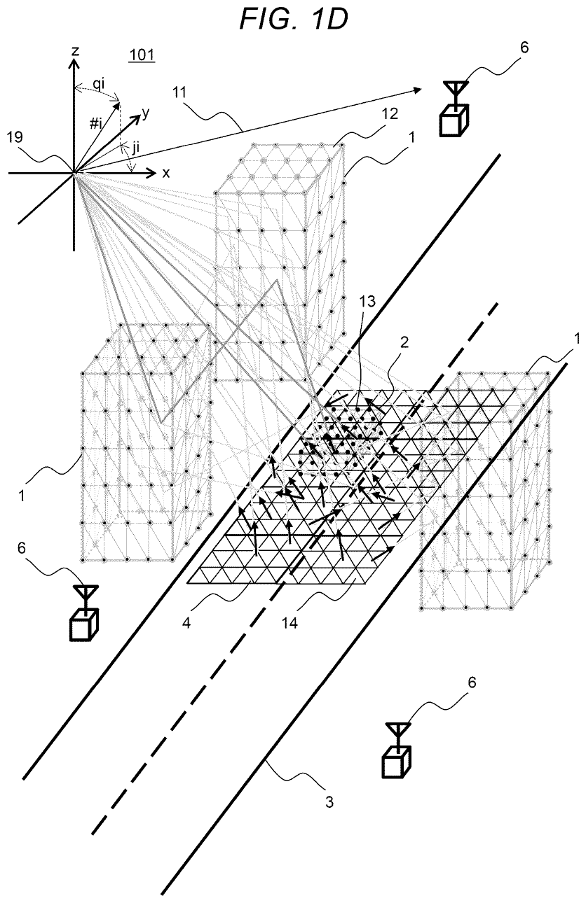

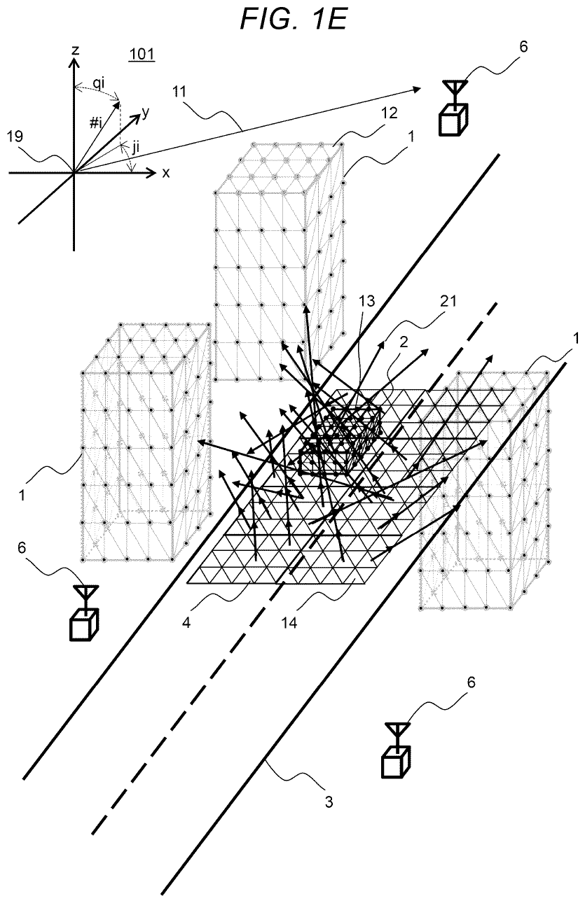

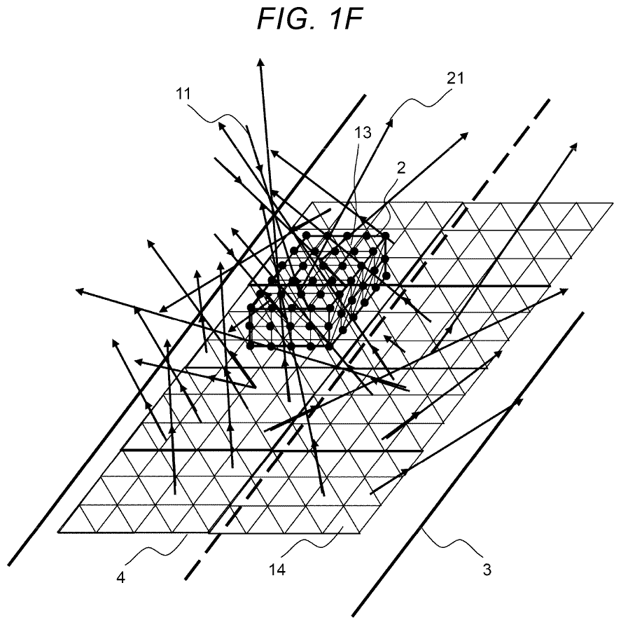

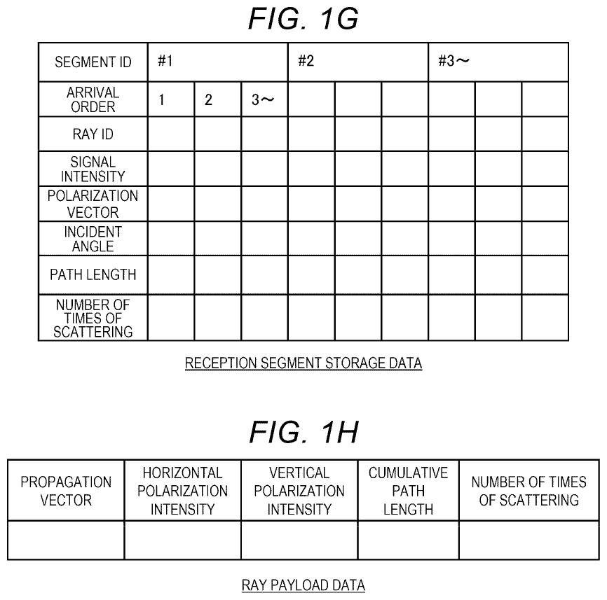

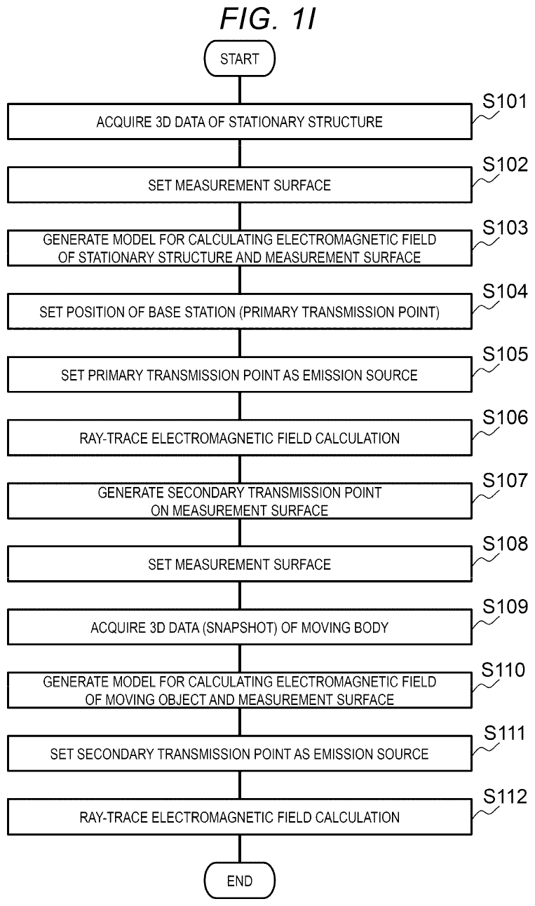

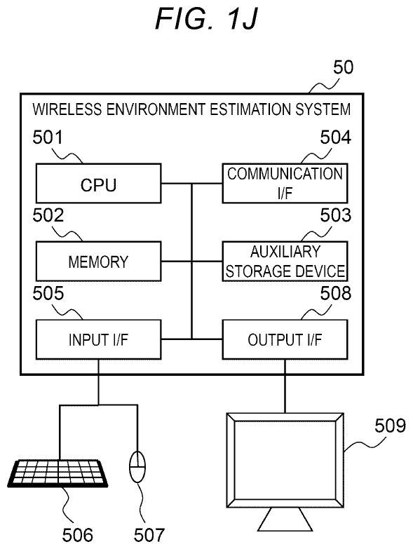

Embodiment 1 of the invention will be described with reference to FIGS. 1a to 1j.

FIG. 1a is a diagram illustrating a wireless digital twin according to Embodiment 1.

In the wireless digital twin according to Embodiment 1, a plurality of stationary structures 1, a moving object 2, a road 3, a measurement surface 4, a base station 5, and a plurality of terminal stations 6 are provided in a service area of a wireless system 101. The measurement surface 4 includes a region through which the moving object 2 may pass on the road 3 and is set above the road 3 to be equal to or less than a height of the moving object 2 (for example, on a surface of the road 3). The base station 5 emits electromagnetic waves into a space to perform wireless communication with the terminal stations 6 disposed at a plurality of points in the service area.

The emitted electromagnetic waves propagate in all directions in a three-dimensional space as rays 11 which have the same properties as light that is a type of electromagnetic wave. A part of the plurality of rays 11 emitted from the base station 5 directly reach the terminal station 6, and the other part of the rays 11 is scattered by the stationary structure 1 and indirectly reach the terminal station 6 as reflected waves and diffracted waves, but most do not reach the terminal station 6 and continue toward infinity.

Since the measurement surface 4 is located near the moving object 2, the ray 11 reaching the moving object 2 always reaches the measurement surface 4 when the moving object 2 is not present. If the intensity, the direction, and the polarization of the ray 11 reaching the measurement surface 4 can be observed, in other words, if these states can be stored, the ray 11 reaching the moving object 2 can be specified by reversely tracing the ray 11 from the measurement surface 4. Since a part of the plurality of rays 11 emitted from the base station 5 is scattered by the stationary structure 1 and a part of the rays 11 is scattered by the moving object 2, the rays 11 that are not scattered by the moving object 2 can be calculated in a virtual environment including only the stationary structure 1 and the measurement surface 4 without the moving object 2.

The ray 11 scattered by the moving object 2 can be generated from the ray 11 that is represented by information about the intensity, the direction, and the polarization on the measurement surface 4 and that is obtained from a calculation result of an electromagnetic field in the virtual environment described above. In general, a size of the stationary structure 1 present in the wireless system 101 is orders of magnitude larger than that of the moving object 2. In addition, since electromagnetic waves are waves, interference between two rays 11 at a location more than half a wavelength apart is extremely small. Therefore, to maintain the accuracy of the electromagnetic field calculation using the rays 11, it is necessary to represent a surface of the stationary structure 1 and a surface of the moving object 2 by dividing the surfaces into a dimension of about half the wavelength. Therefore, a calculation amount of an interaction between the stationary structure 1 and the ray 11 is orders of magnitude larger than a calculation amount of an interaction between the moving object 2 and the ray 11. The reduction in the calculation of the interaction between the ray 11 and the stationary structure 1 has a significant effect on reducing the calculation time for the electromagnetic field calculation using the ray 11.

In the present embodiment, as illustrated in FIG. 1b, in a cyberspace in which the stationary structure 1 and the moving object 2 are simultaneously present, the surface of the stationary structure 1 is divided by minute segments 12 each having a size of about a half wavelength, the surface of the moving object 2 is divided by minute segments 13 each having a size of about a half wavelength, the measurement surface 4 is configured by minute segments 14 each having a size of about a half wavelength, and the base station 5 is set as a transmission point 19 that emits the ray 11 in all directions in the space.

Next, as illustrated in FIG. 1c, a region in which the moving object 2 may be present is specified in advance, the measurement surface 4 is provided in the specified region, the stationary structure 1 whose surface is divided and expressed by the minute segments 12 each having a size of about a half wavelength and the measurement surface 4 formed by the minute segments 14 each having a size of about a half wavelength are formed in a cyberspace, a large number of rays 11 is emitted in all directions in the space using the base station 5 as the transmission point 19 to perform an electromagnetic field analysis, and the rays 11 representing the electromagnetic field on the measurement surface 4 by information about the intensity, the direction, and the polarization are stored as illustrated in FIG. 1d.

Subsequently, as illustrated in FIG. 1e, the moving object 2 whose surface is divided and expressed by the minute segments 13 each having a size of about a half wavelength is formed in a cyberspace, a plurality of rays 21 obtained by reversely following the rays 11 incident on the measurement surface 4 are emitted using each of the minute segment 14 on the measurement surface 4 as a secondary transmission point to perform an electromagnetic field analysis, and an electromagnetic field distribution in the entire region in the service area of the wireless system 101 is calculated. At this time, as illustrated in FIG. 1f, in the calculation of the interaction between the ray 21 and the minute segments 13 that divisionally express the moving object 2, since the ray 21 emitted from the measurement surface 4 is a ray obtained by reversely following the ray 11 incident on the measurement surface 4, it should be noted that the law of refraction is reversed such that the scattering phenomenon of the ray 21 matches the scattering phenomenon of the original ray 11 that occurs on the minute segments 13 that divisionally expresses the moving object 2.

FIGS. 1g and 1h illustrate an example attributes given to the ray 11 and the ray 21 and a data configuration of the measurement surface 4 which are necessary for ray tracing calculation that is an example of electromagnetic field calculation according to the present embodiment.

As illustrated in FIG. 1g, since the plurality of rays 11 and rays 21 reach the measurement surface 4, IDs for identifying the rays 11 and 21 that reach the minute segments 14 forming the measurement surface 4, signal intensities of the rays 11 and 21 corresponding to the respective IDs, polarization vectors, incident angles with respect to the minute segment 14, path lengths until reaching the segment, and the number of times of scattering are stored. The path length and the number of times of scattering are for discarding the rays 11 and 21 whose signal intensity decreases to such an extent that communication quality cannot be maintained in the ray tracing calculation. As illustrated in FIG. 1h, a payload for storing a propagation vector indicating a traveling direction, a horizontal polarization intensity, a vertical polarization intensity, a cumulative path length, and the number of times of scattering is added to each of the rays 11 and 21 emitted from the transmission point 19. The payload information is information required for calculation on the measurement surface 4.

FIG. 1i illustrates a procedure of processing executed by a wireless environment estimation system 50 according to the present embodiment. First, three-dimensional structure data of the stationary structure 1 is acquired (S101), and the measurement surface 4 is set to include a region through which the moving object 2 may pass on the road 3 and is set to be above the road 3 to be equal to or less than the height of the moving object 2 (S102).

Then, a calculation model required for the electromagnetic field analysis is generated from the structure data of the stationary structure 1 and the information about the measurement surface 4 (S103), the transmission point 19 for emitting the ray 11 in all directions in the space is set at a position of the base station 5 (S104), the ray 11 is emitted using the set transmission point 19 as an emission source (S105), and the electromagnetic field is calculated by a ray tracing method (S106).

Then, from the information about the ray 11 that reaches each of the minute segment 14 on the measurement surface 4, which is derived by the electromagnetic field calculation, the secondary transmission point for emitting the plurality of rays 21 obtained by reversely following the reached ray 11 from each minute segment 14 on the measurement surface 4 is generated (S107). Then, the structure data of the stationary structure 1 is acquired, the measurement surface 4 is reset on the stationary structure 1 (S108), the 3D data (snapshot) of a position of the moving object 2 at a specific time point is acquired (S109), a calculation model required for the electromagnetic field analysis is generated from the structure data of the moving object 2 and the information about the measurement surface 4 (S110), the ray 21 is emitted in a specific direction in the space using the generated secondary transmission point as the emission source (S111), and the electromagnetic field is calculated by the ray tracing method (S112).

Then, a sum of an electromagnetic field estimation result calculated in step S106 and an electromagnetic field estimation result calculated in step S112 is calculated to derive the electromagnetic field of the entire environment of the service area of the wireless system 101.

As illustrated in FIG. 1j, the wireless environment estimation system 50 that executes the processing illustrated in FIG. 1i is implemented by a computer including a processor (CPU) 501, a memory 502, an auxiliary storage device 503, and a communication interface 504. The wireless environment estimation system 50 may include an input interface 505 and an output interface 508.

The processor 501 is an arithmetic device that executes a program stored in the memory 502. Functions of the functional units of the wireless environment estimation system 50 are implemented by the processor 501 executing various programs. A part of the processing executed by the processor 501 executing the program may be executed by another arithmetic device (for example, hardware such as an ASIC or an FPGA).

The memory 502 includes a ROM that is a non-volatile storage element and a RAM that is a volatile storage element. The ROM stores a fixed program (for example, BIOS). The RAM is a high-speed and volatile storage element such as a dynamic random access memory (DRAM), and temporarily stores the program executed by the processor 501 and data used when the program is executed.

The auxiliary storage device 503 is, for example, a large-capacity nonvolatile storage device such as a magnetic storage device (HDD) or a flash memory (SSD). The auxiliary storage device 503 stores the data used when the processor 501 executes the program and the program executed by the processor 501. That is, the program is read from the auxiliary storage device 503, loaded onto the memory 502, and executed by the processor 501 to implement the functions of the wireless environment estimation system 50.

The communication interface 504 is a network interface device that controls communication with another device according to a predetermined protocol.

The input interface 505 is an interface that is connected to an input device such as a keyboard 506 and a mouse 507 and that receives an input from an operator. The output interface 508 is an interface connected to an output device such as a display device 509 and a printer (not illustrated) and that outputs an execution result of the program in a format visible to a user. A user terminal connected to the wireless environment estimation system 50 via a network may provide the input device and the output device. In this case, the wireless environment estimation system 50 may have a function of a web server, and the user terminal may access the wireless environment estimation system 50 by a predetermined protocol (for example, http).

The program executed by the processor 501 is provided to the wireless environment estimation system 50 via a removable medium (CD-ROM, flash memory, or the like) or the network, and is stored in the non-volatile auxiliary storage device 503 which is a non-transitory storage medium. Therefore, the wireless environment estimation system 50 may include an interface for reading data from the removable medium.

The wireless environment estimation system 50 is a computer system implemented on one physical computer or a plurality of computers implemented logically or physically, and may operate on a virtual computer constructed on a plurality of physical computer resources. For example, a plurality of programs for implementing the functions of the wireless environment estimation system 50 may be executed on separate physical or logical computers, or may be executed on a single physical or logical computer in combination.

In the present embodiment, the number of rays 11 in the electromagnetic field calculation and the number of minute segments 14 used in the calculation for the rays 11 formed on the moving object 2 and the measurement surface 4 are extremely small compared to the number of rays 11 in the electromagnetic field calculation and the number of minute segments 12 used in the calculation for the stationary structure 1 and the measurement surface 4, and the time required for the electromagnetic field calculation for the rays 21 formed on the moving object 2 and the measurement surface 4 can be shortened. Therefore, a communication environment can be predicted in a short time in the future, and the consumption of communication resources can be reduced while ensuring the reliability of communication. Further, there is an effect of implementing a wireless digital twin that reproduces a change in radio wave environment in the service area of the wireless system 101 due to a change in the moving object 2, estimating a change in radio wave environment caused by the moving object 2, and improving the stability and reliability of the wireless remote control of the device in the same area using the estimation result of the electromagnetic environment at the future time point.

### Embodiment 2

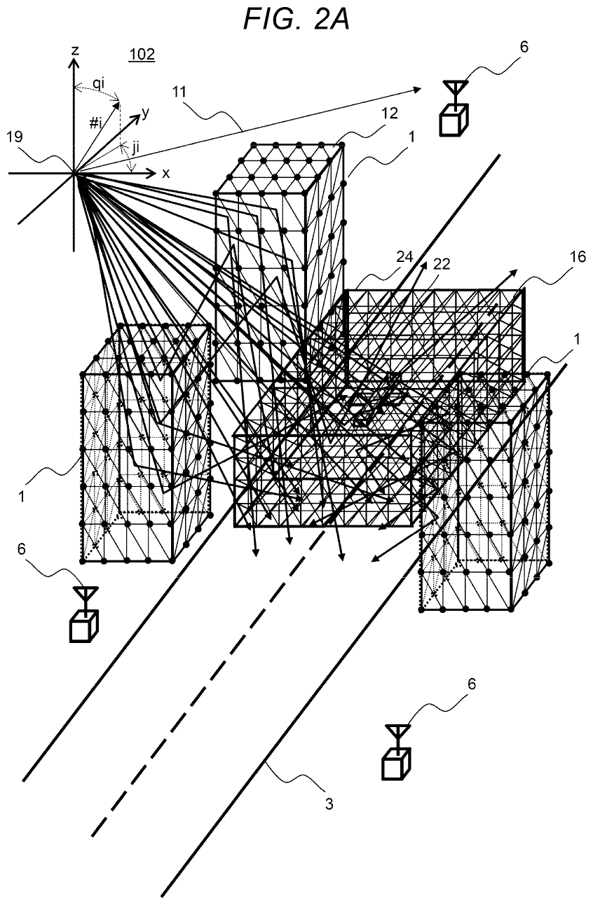

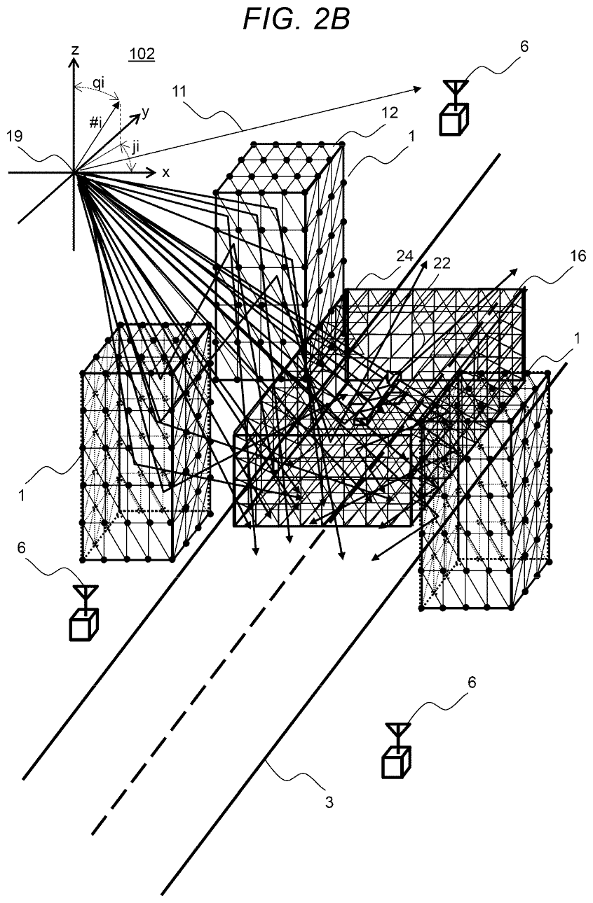

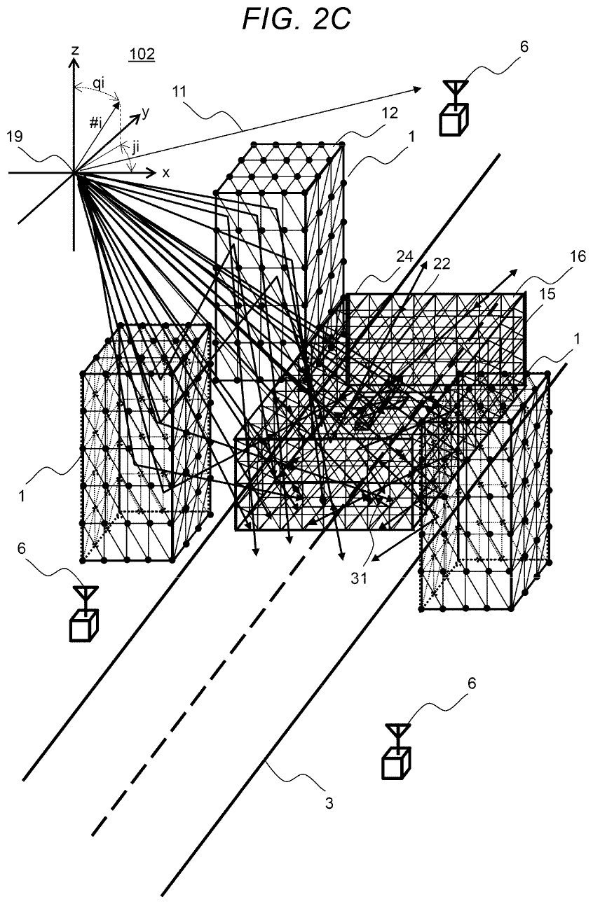

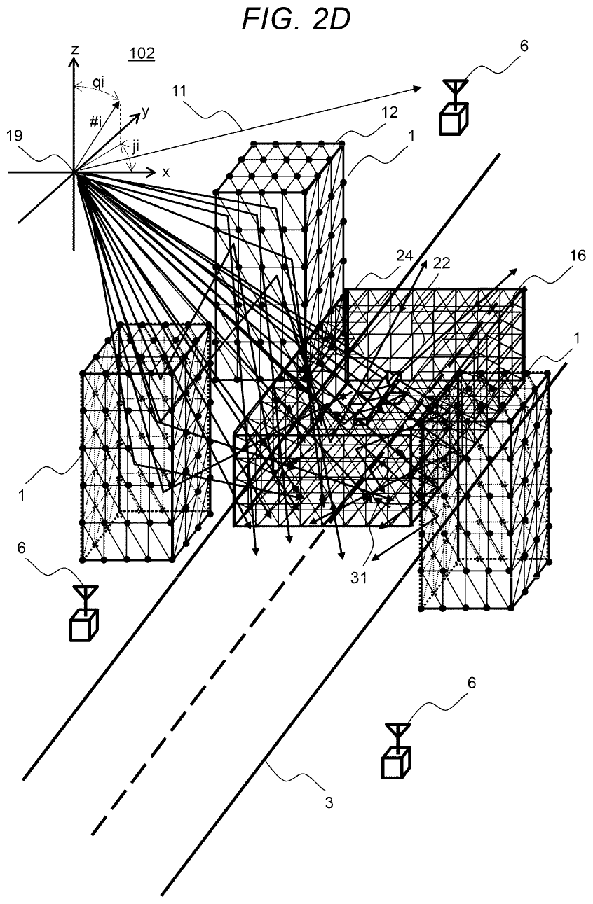

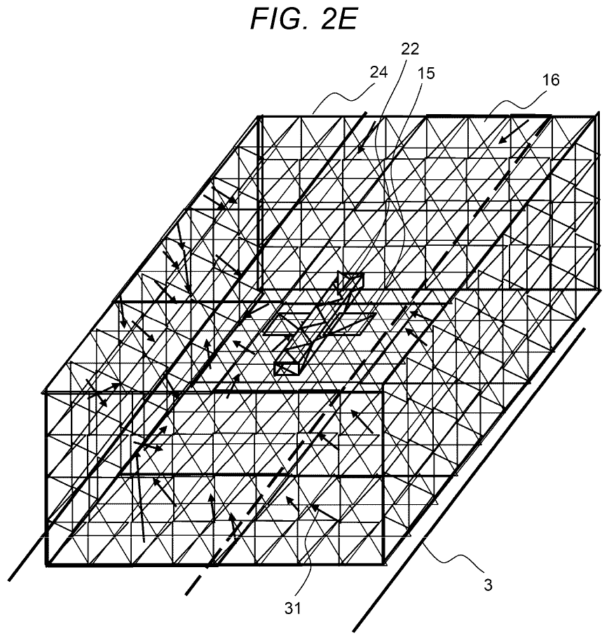

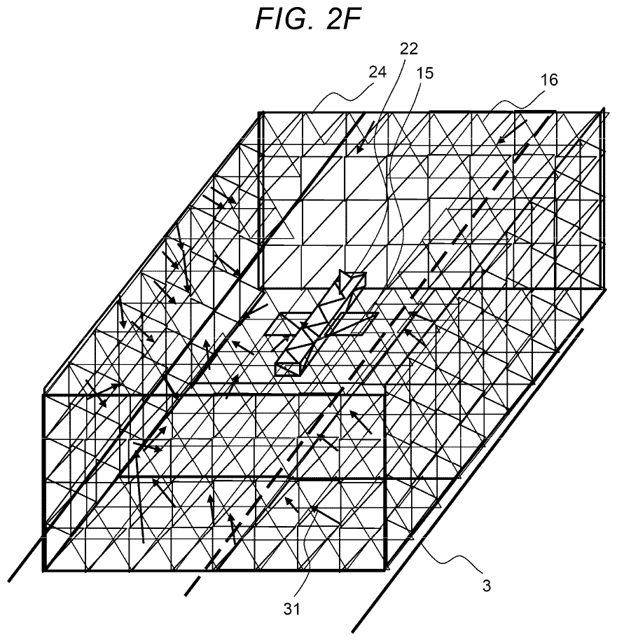

Embodiment 2 of the invention will be described with reference to FIGS. 2a to 2f. In Embodiment 2, differences from Embodiment 1 described above will be mainly described, the same configurations and processing as those in Embodiment 1 will be denoted by the same reference numerals, and descriptions thereof will be omitted.

In Embodiment 1, the moving object 2 and the measurement surface 4 that move in a planar manner in the service area of the wireless system 101 are provided, whereas Embodiment 2 is different from Embodiment 1 in that a flying object 22 and a measurement closed surface 24 that move three-dimensionally in the space in a service area of the wireless system 102 are provided. FIGS. 2a and 2b are diagrams illustrating a wireless digital twin according to Embodiment 2, and FIG. 2b is a diagram omitting a minute segment 16 that does not serve as a secondary transmission point. FIGS. 2c and 2d are diagrams illustrating rays 31 emitted from the minute segment 16, and FIG. 2d is a diagram omitting the minute segment 16 that does not serve as the secondary transmission point. FIGS. 2e and 2f are enlarged views of the measurement closed surface 24, and FIG. 2f is a view omitting the minute segment 16 that does not serve as the secondary transmission point.

As illustrated in FIGS. 2a and 2b, the measurement closed surface 24 includes a three-dimensional region in which the flying object 22 may be present, and is expressed by a closed figure formed by a plurality of the minute segments 16 that are surface elements. In Embodiment 2, similarly to Embodiment 1, the electromagnetic field calculation is performed in a cyberspace in which only the stationary structure 1 in which the flying object 22 is not present is present, and information about the intensity, the direction, and the polarization of each minute segment 16 is stored for the ray 11 passing through the measurement closed surface 24. The ray 11 stored in each minute segment 16 is only a ray emitted from an inside to an outside of the measurement closed surface 24.

Subsequently, as illustrated in FIGS. 2c, 2d, 2e, and 2f, the ray 31 is emitted based on the information about the intensity, the direction, and the polarization stored in each minute segment 16. The ray 31 is a ray emitted from the inside to the outside of the measurement closed surface 24, is emitted in a direction opposite to that of the ray 11, and is subjected to the same scattering calculation as that of the ray 21 according to Embodiment 1. Calculation when the rays 31 interact with minute segments 15 that divisionally express a surface of the flying object 22 is the same as the calculation when the rays 21 interact with the minute segments 13 that divisionally express the moving object 2 according to Embodiment 1.

According to the present embodiment, there is an effect in implementing a wireless digital twin for estimating the wireless communication characteristics in the wireless communication area including an object that travels three-dimensionally according to the movement of the moving object.

### Embodiment 3

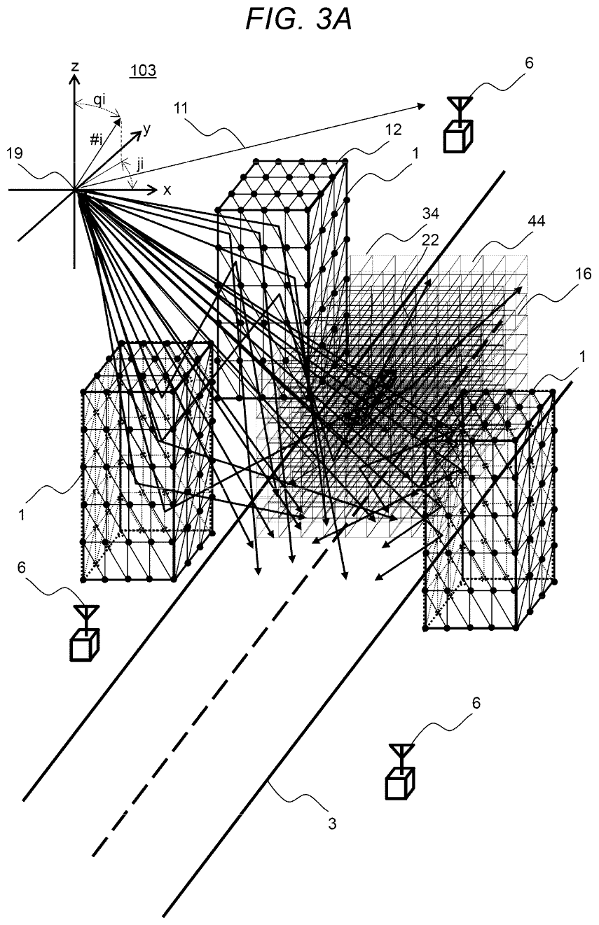

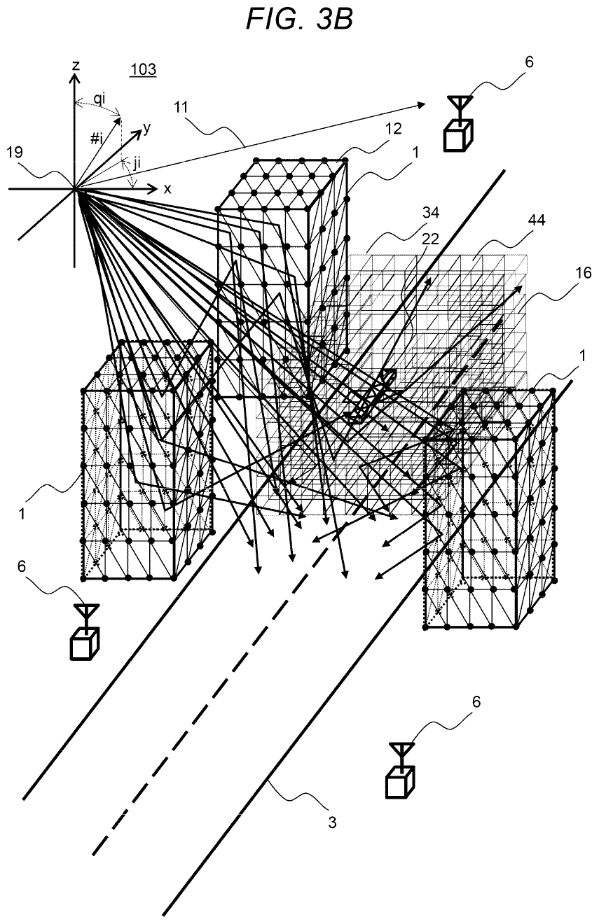

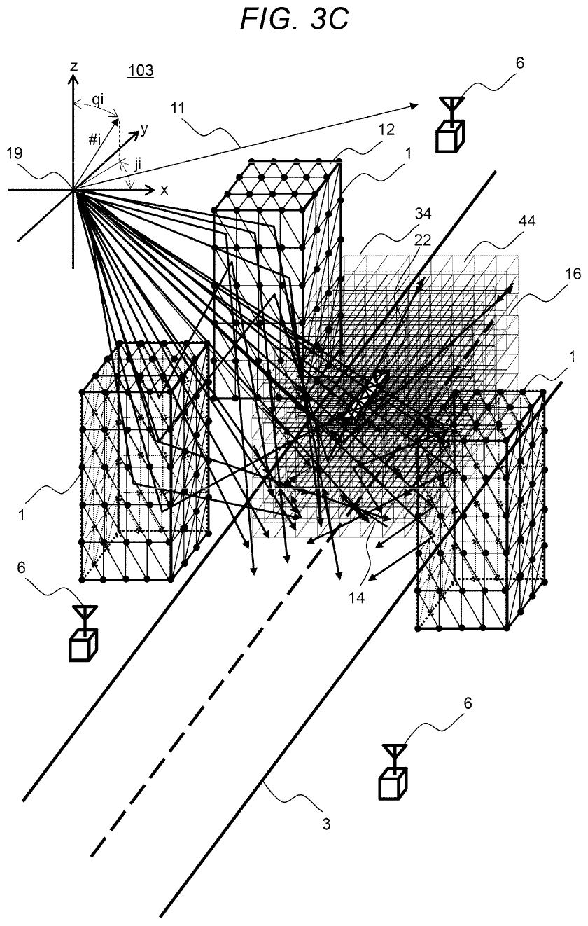

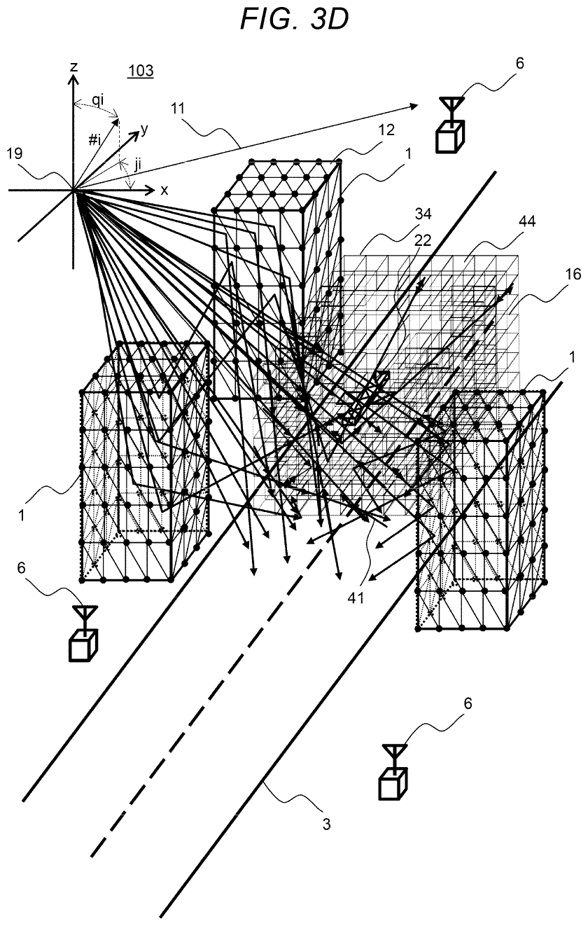

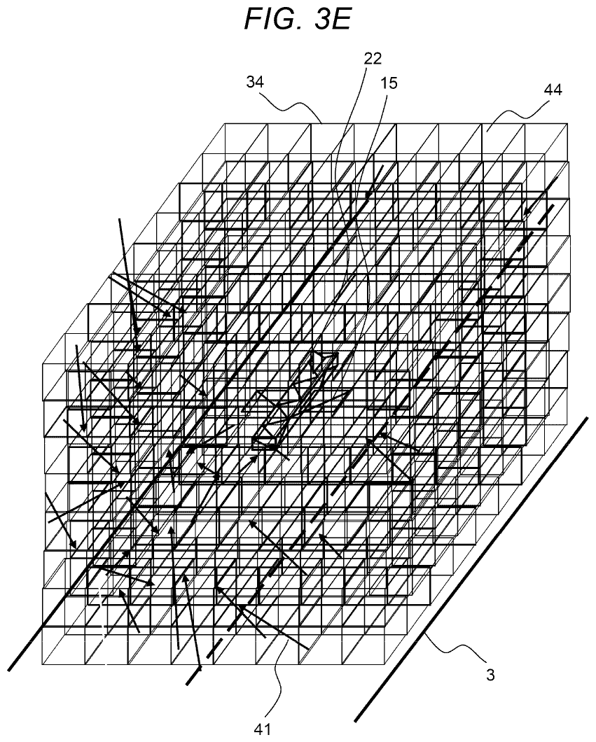

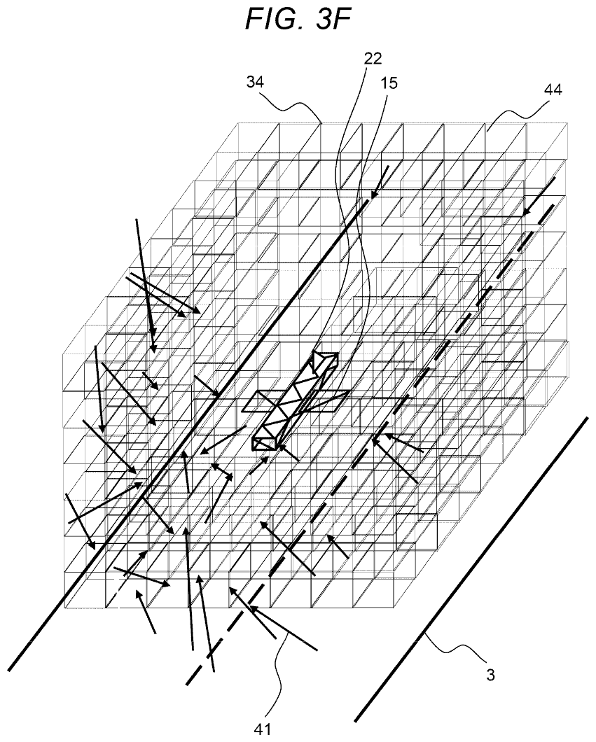

Embodiment 3 of the invention will be described with reference to FIGS. 3a to 3f. In Embodiment 3, differences from Embodiment 1 described above will be mainly described, the same configurations and processing as those in Embodiment 1 will be denoted by the same reference numerals, and descriptions thereof will be omitted.

In Embodiment 1, the moving object 2 and the measurement surface 4 that move in a planar manner in the service area of the wireless system 101 are provided, whereas Embodiment 3 is different from Embodiment 1 in that the flying object 22 and a measurement shell 34 that move three-dimensionally in a space in a service area of a wireless system 103 are provided. FIGS. 3a and 3b are diagrams illustrating a wireless digital twin according to Embodiment 3, and FIG. 3b is a diagram omitting the minute segment 16 that does not serve as a secondary transmission point. FIGS. 3c and 3d are diagrams illustrating the rays 31 emitted from the minute segment 16, and FIG. 3d is a diagram omitting the minute segment 16 that does not serve as the secondary transmission point. FIGS. 3e and 3f are enlarged views of the measurement shell 34, and FIG. 3f is a view omitting the minute segment 16 that does not serve as the secondary transmission point.

As illustrated in FIGS. 3a and 3b, the measurement shell 34 includes a three-dimensional region in which the flying object 22 may be present, and is expressed in a closed shape formed by a plurality of minute voxels 44 that are three-dimensional elements. In Embodiment 3, similarly to Embodiment 1, the electromagnetic field calculation is performed in a cyberspace in which only the stationary structure 1 in which the flying object 22 is not present is present, and information about the intensity, the direction, and the polarization of each minute voxel 44 is stored for the ray 11 passing through the measurement shell 34. The ray 11 stored in each minute voxel 44 is only a ray emitted from an inside to an outside of the measurement shell 34.

Subsequently, as illustrated in FIGS. 3c and 3d, a ray 41 is emitted based on the information about the intensity, the direction, and the polarization stored in each minute voxel 44. The ray 41 is a ray emitted from the inside to the outside of the measurement shell 34, is emitted in a direction opposite to that of the ray 11, and is subjected to the same scattering calculation as that of the ray 21 according to Embodiment 1. Calculation when the rays 41 interact with minute segments 15 that divisionally express a surface of the flying object 22 is the same as the calculation when the rays 21 interact with the minute segments 13 that divisionally express the moving object 2 according to Embodiment 1. In Embodiment 2, the calculation accuracy of the interaction between the ray 11 incident in a direction close to a direction perpendicular to a normal line of the minute segment 16 and the minute segment 16 deteriorates. In the present embodiment, since the ray 11 is incident on the minute voxel 44, when the ray 11 is incident from a direction close to perpendicular to the normal line of one surface of the minute voxel 44, the ray 11 interacts with the other surface of the minute voxel 44, and thus it is possible to prevent a deterioration of the calculation accuracy of the interaction of the minute voxel 44 as a whole.

According to the present embodiment, it is possible to improve the wireless communication characteristic estimation accuracy of a wireless digital twin for estimating the wireless communication characteristics in the wireless communication area including an object that travels three-dimensionally according to the movement of the moving object.

### Embodiment 4

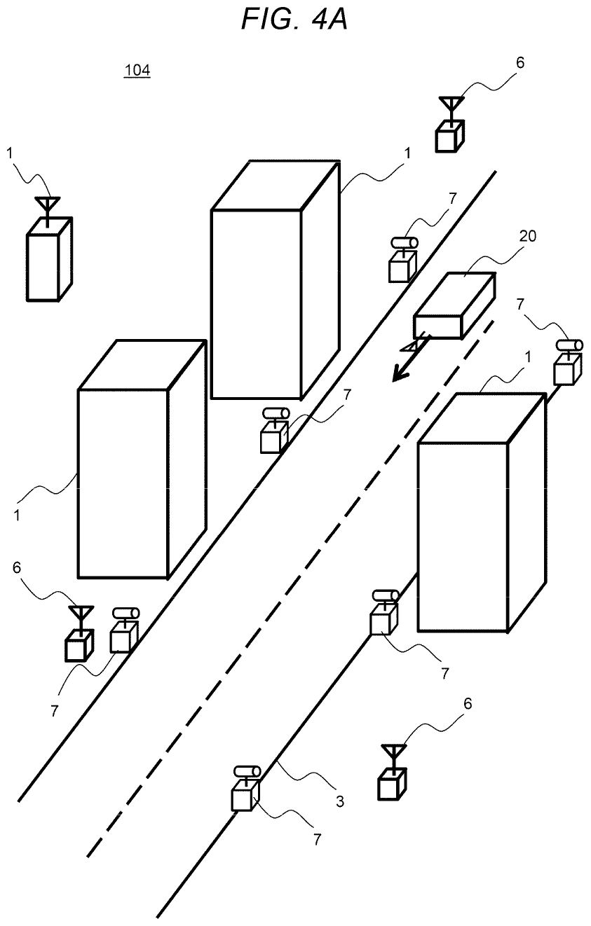

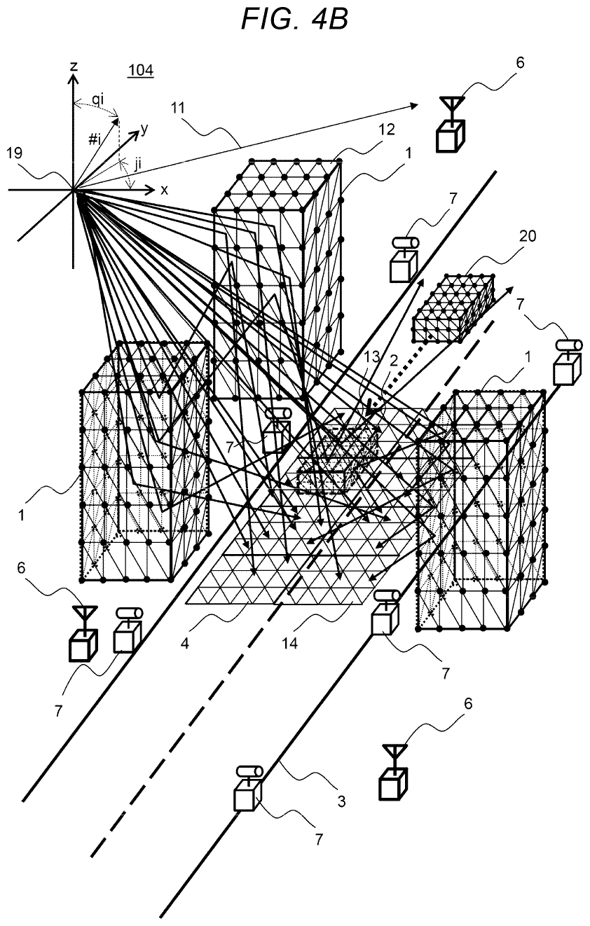

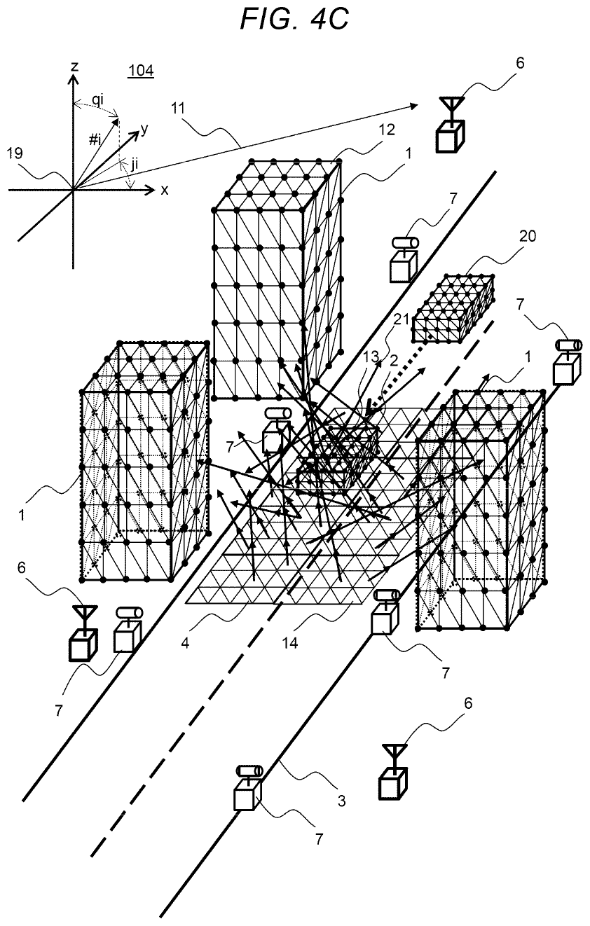

Embodiment 4 of the invention will be described with reference to FIGS. 4a to 4c. In Embodiment 4, differences from Embodiment 1 described above will be mainly described, the same configurations and processing as those in Embodiment 1 will be denoted by the same reference numerals, and descriptions thereof will be omitted.

FIG. 4a is a diagram illustrating a wireless digital twin according to Embodiment 4.

Embodiment 4 is different from Embodiment 1 in that LiDARs 7 for measuring a position and a shape of an object in a service area of a wireless system 104, such as the moving object 2 traveling in the service area, are provided.

The LiDAR 7 can observe the position and the shape of a moving object 20 present in the service area in time series, and can measure a movement speed and a movement direction of the moving object 20 based on the observed position and shape. A method for estimating, in a cyberspace, the electromagnetic field environment at a future time point in the service area by using the movement speed and the movement direction of the moving object 20 acquired by the LiDARs 7 will be described with reference to FIGS. 4b and 4c. First, as illustrated in FIG. 4b, the wireless environment estimation system 50 performs electromagnetic field calculation based on structure data related to the stationary structure 1 and the measurement surface 4, uses information about the movement speed and the movement direction of the moving object 2 acquired by the LiDARs 7 to calculate a position and a posture of the moving object 2 at a future time point in the cyberspace, and uses the structure data related to the moving object 2 at the future time point and the plurality of rays 21 emitted from the measurement surface that is derived by the electromagnetic field calculation related to the stationary structure 1 and the measurement surface 4 to estimate an electromagnetic field distribution in the service area at a future time point.

According to the present embodiment, since the electromagnetic field distribution at a future time point in the service area of the wireless system 104 can be estimated for the moving object 2 and the wireless communication quality in the same area at the future time point can be predicted from the estimated electromagnetic field distribution, the safety and the stability of operations of a device controlled by wireless communication can be improved.

### Embodiment 5

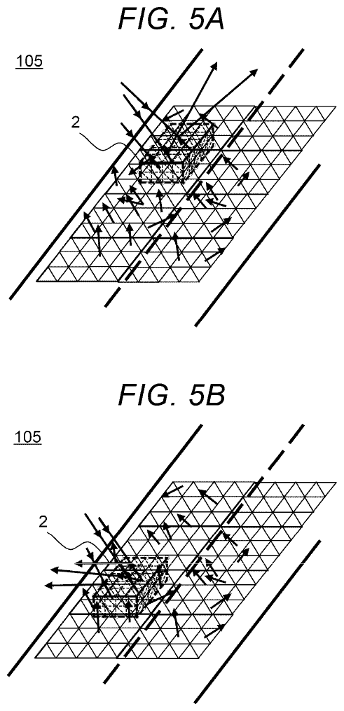

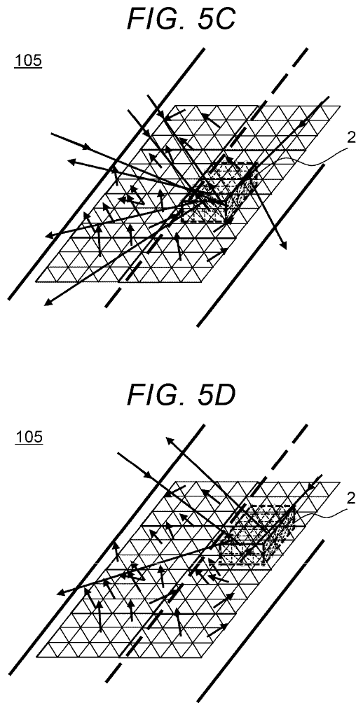

Embodiment 5 of the invention will be described with reference to FIGS. 5a to 5d. In Embodiment 5, differences from Embodiment 1 described above will be mainly described, the same configurations and processing as those in Embodiment 1 will be denoted by the same reference numerals, and descriptions thereof will be omitted.

FIGS. 5a to 5d are diagrams illustrating a wireless digital twin according to Embodiment 5.

In Embodiment 5, a position and a posture of the moving object 2 in a service area of a wireless system 105 are observed in time series by the LiDARs 7 as in i Embodiment 4, and electromagnetic field distributions at time points are sequentially calculated. A variation of the electromagnetic field in the service area can be quantitatively grasped by calculating a difference of the obtained electromagnetic field distributions at the time points. For example, the moving object 2 illustrated in FIG. 5a moves to a position illustrated in FIG. 5b after a predetermined time, and the electromagnetic field environment changes. The moving object 2 illustrated in FIG. 5c moves to a position illustrated in FIG. 5d after a predetermined time, and the electromagnetic field environment changes. Since a magnitude of the variation of the electromagnetic field has a reverse relationship with the stability of the wireless communication quality, it is possible to know a dynamic change in the wireless communication quality in the service area, and there is an effect on the terminal station arrangement design to ensure stable operations of the wireless system 105.

### Embodiment 6

Embodiment 6 of the invention will be described with reference to FIG. 6. In Embodiment 6, differences from Embodiment 5 described above will be mainly described, the same configurations and processing as those in Embodiment 5 will be denoted by the same reference numerals, and descriptions thereof will be omitted.

FIG. 6 is a diagram illustrating a wireless digital twin according to Embodiment 6.

Embodiment 6 is different from Embodiment 5 in that cameras 8 for measuring a position and a shape of an object in a service area of a wireless system 106, such as the moving object 2 traveling in the service area, are provided.

The camera 8 can observe the position and the shape of the moving object 2 present in the service area in time series, and the wireless environment estimation system 50 can measure a movement speed and a movement direction of the moving object 2 based on the observed position and shape. A relative position between the moving object 2 and the stationary structure 1 and a size, a movement direction, and a movement speed of the moving object 2 can be estimated by using a plurality of pieces of image data acquired by the cameras 8 at different time points and from different locations. Then, a position and a posture of the moving object 2 at a future time point in a cyberspace are calculated by using the estimated relative position, size, movement direction, and movement speed of the moving object 2, and an electromagnetic field distribution in the service area at the future time point is estimated by using structure data related to the moving object 2 at the future time point and the plurality of rays 21 emitted from the measurement surface derived by the electromagnetic field calculation related to the stationary structure 1 and the measurement surface 4. In this way, the electromagnetic field environment at the future time point in the service area can be estimated in the cyberspace by using the movement speed and the movement direction of the moving object 2 obtained by the cameras 8.

Since the camera 8 has economical hardware than the LiDAR, it is possible to reduce the cost of introducing the wireless digital twin for estimating the wireless communication characteristics in the wireless communication area according to the movement of the moving object.

### Embodiment 7

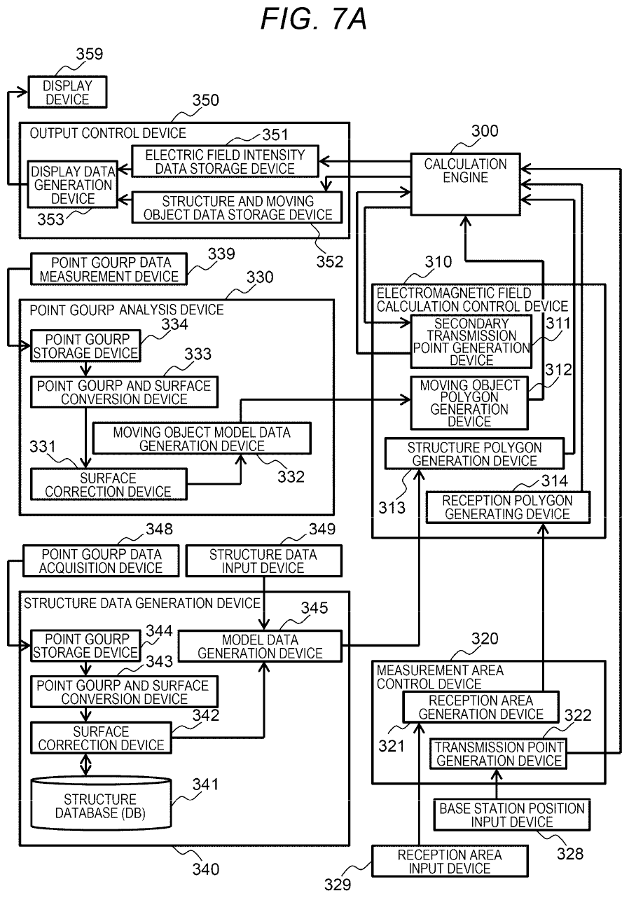

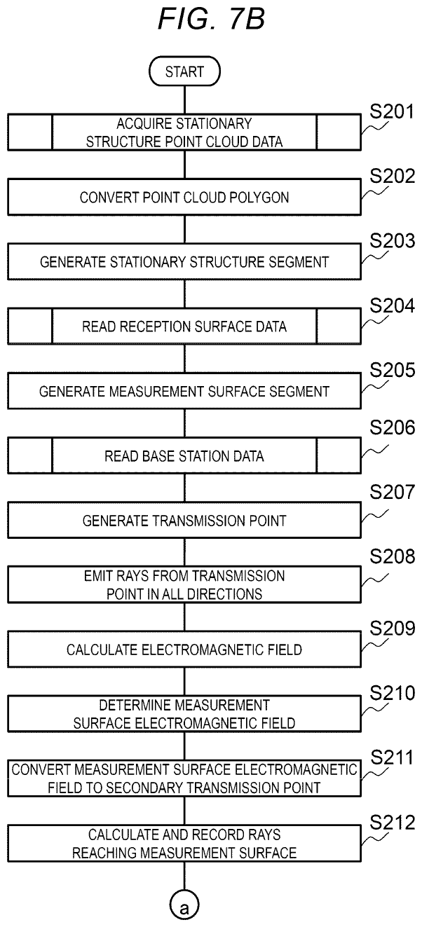

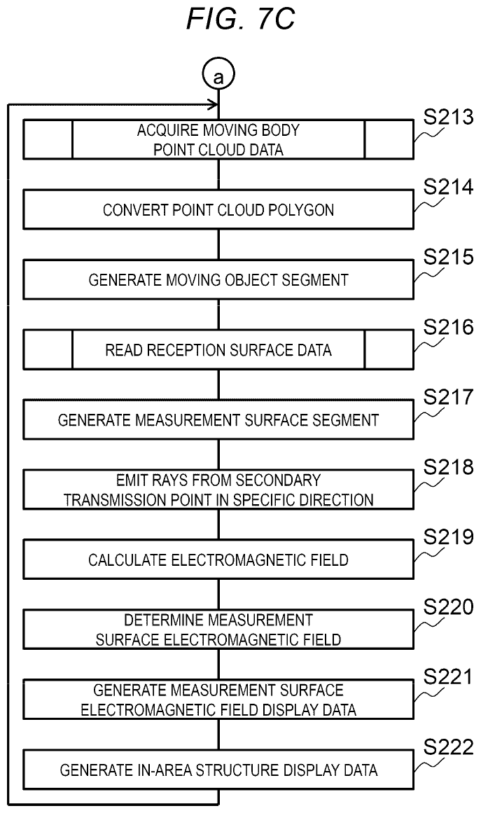

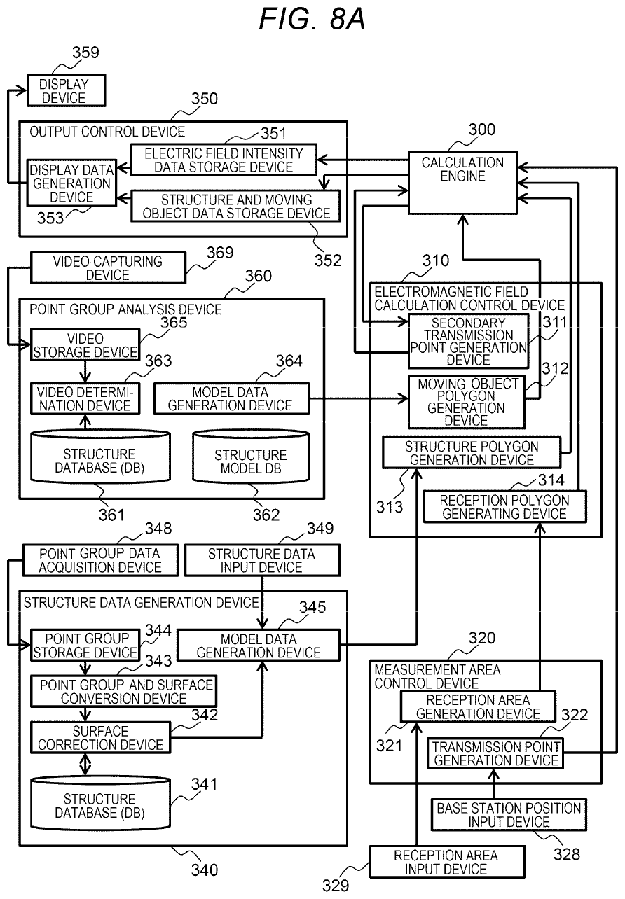

Embodiment 7 of the invention will be described with reference to FIGS. 7a to 7c. In Embodiment 7, differences from Embodiment 1 described above will be mainly described, the same configurations and processing as those in Embodiment 1 will be denoted by the same reference numerals, and descriptions thereof will be omitted.

FIG. 7a is a diagram illustrating a configuration of a wireless environment estimation system 50 according to Embodiment 7.

As main components, the wireless environment estimation system 50 includes a calculation engine 300 that performs electromagnetic field calculation in a service area of the wireless system 101, an electromagnetic field calculation control device 310 that supplies various types of data required by the calculation engine 300 and manages calculation results obtained by the calculation engine 300, a measurement area control device 320 that provides data required by the calculation engine 300 for calculation, a point group analysis device 330 that provides the data required by the calculation engine 300 for calculation, a structure data generation device 340 that generates structure data, and an output control device 350 that outputs various trial results using a digital twin to an outside. Next, operations of each component will be described in detail.

First, the electromagnetic field calculation control device 310 includes a secondary transmission point generation device 311, a moving object polygon generation device 312, a structure polygon generation device 313, and a reception polygon generation device 314. The reception polygon generation device 314 determines the measurement surface 4 by using the data transmitted from the measurement area control device 320, generates reception polygons serving as the minute segments 14 forming the determined measurement surface 4, and outputs the reception polygons to the calculation engine 300. The structure polygon generation device 313 generates reception polygons serving as the minute segments 12 related to the stationary structure 1 by using the data transmitted from the structure data generation device 340, and outputs the reception polygons to the calculation engine 300. The moving object polygon generation device 312 generates reception polygons serving as the minute segments 13 related to the moving object 2 by using the data transmitted from the point group analysis device 330, and outputs the reception polygons to the calculation engine 300. The secondary transmission point generation device 311 generates a secondary transmission point by using a result of the electromagnetic field calculation by the calculation engine 300, and outputs the secondary transmission point to the calculation engine 300.

Secondly, the measurement area control device 320 includes a reception area generation device 321 and a transmission point generation device 322, and outputs data related to a reception surface and a transmission point 19. The reception area generation device 321 acquires, from a reception area input device 329, information about a region for which the wireless communication quality is analyzed in the wireless digital twin, and outputs the information to the reception area generation device 321. The transmission point generation device 322 acquires information about an emission point of the ray 11 in the electromagnetic field calculation from a base station position input device 328, and outputs the information to the transmission point generation device 322.

Thirdly, the point group analysis device 330 includes a surface correction device 331, a moving object model data generation device 332, a point group and surface conversion device 333, and a point group storage device 334. The point group storage device 334 acquires an output of a point group data measurement device 339 that acquires the structure data of the moving object 2 in the service area of the wireless system 101 as a point group, stores the acquired data, and outputs the data to the point group and surface conversion device 333. The point group and surface conversion device 333 converts the point group into a planar segment and outputs the planar segment to the surface correction device 331. The surface correction device 331 checks a connection state of the planar segment output from the point group and surface conversion device 333, corrects a defect, and outputs information about the planar segment to the moving object model data generation device 332. The moving object model data generation device 332 outputs the information about the planar segment to an outside of the point group analysis device 330.

Fourth, the structure data generation device 340 includes a structure database 341, a surface correction device 342, a point group and surface conversion device 343, a point group storage device 344, and a model data generation device 345. The point group storage device 344 acquires the structure data of the stationary structure 1 in the service area of the wireless system 101 as a point group from a point group data acquisition device 348, stores the acquired data, and outputs the data to the point group and surface conversion device 343. The point group and surface conversion device 343 converts the input point group into a planar segment and outputs the planar segment to the surface correction device 342. The surface correction device 342 checks a connection state of the planar segment output from the point group and surface conversion device 343, corrects a defect, and outputs information about the planar segment to the structure database 341. Data related to a structure present in the service area may be generated from a point group obtained by actual measurement, or may be output to the structure data generation device 340 by the structure data input device 349. The model data generation device 345 outputs the data related to the structure output from the structure data input device 349 and the data related to the structure read from the structure database 341 to an outside of the structure data generation device 340.

Fifth, the output control device 350 includes an electric field intensity data storage device 351, a structure and moving object data storage device 352, and a display data generation device 353. The electric field intensity data storage device 351 acquires an electromagnetic field analysis result from the calculation engine 300. The structure and moving object data storage device 352 acquires, from the calculation engine 300, data related to the stationary structure 1 and the moving object 2 used by the calculation engine 300 for the electromagnetic field calculation. The display data generation device 353 generates image data representing the electromagnetic field intensity by using the data acquired by the electric field intensity data storage device 351 and the data acquired by the structure and moving object data storage device 352, and outputs the image data to a display device 359.

FIGS. 7b and 7c are flowcharts of processing in which the wireless environment estimation system 50 according to Embodiment 7 generates a wireless digital twin.

First, the wireless environment estimation system 50 acquires point group data of a stationary structure (S201), converts the acquired point group into a polygon (S202), generates a minute segment in which rays related to the stationary structure interact from the polygon (S203), and reads data related to a reception surface (S204). Then, the wireless environment estimation system generates a measurement surface from the data related to the reception surface and generates a minute segment that interacts with the ray on the measurement surface (S205), reads base station data (S206), and generates a transmission point that emits the rays 11 in all directions in the space from the read base station data (S207).

Then, the wireless environment estimation system 50 emits the ray 11 from the transmission point 19 (S208), executes the electromagnetic field calculation in the service area of the wireless system 101 by the emitted ray 11 (S209), determines an electromagnetic field distribution generated on the measurement surface 4 by a result of the electromagnetic field calculation (S210), obtains the plurality of transmission points 19 that secondarily emit the rays 21 from the minute segment 14 generated on the measurement surface 4 by the determined electromagnetic field distribution (S211), and calculates the traveling direction, the intensity, and the polarization characteristic of the secondarily emitted ray 21 by using the result of the electromagnetic field calculation on the measurement surface (S212).

Then, the wireless environment estimation system 50 acquires point group data of the moving object 2 (S213), converts the acquired point group into a polygon (S214), and generates the minute segment 13 in which the rays 11 related to the moving object 2 interact from the converted polygon (S215). Then, the wireless environment estimation system 50 reads data related to a reception surface (S216), and generates the minute segment 14 that interacts with the ray 11 on the measurement surface generated from the read data related to the reception surface (S217).

Then, the wireless environment estimation system 50 emits the ray 21 in a specific direction from the plurality of secondary transmission points generated on the measurement surface (S218), executes electromagnetic field calculation in the service area of the wireless system 101 by the emitted ray 21 (S219), determines an electromagnetic field distribution generated on the measurement surface 4 from the result of the electromagnetic field calculation (S220), generates data for displaying the determined electromagnetic field distribution (S221), and creates data for displaying a structure including the stationary structure 1 and the moving object 2 in the service area (S222).

Since the location and the posture of the moving object 2 change every moment within the service area of the wireless system 101, the processing returns to step S213 after the processing of step S222.

According to the present embodiment, there is an effect in implementing the wireless digital twin in which the movement of the moving object 2 in the wireless communication area including the three-dimensionally traveling object is detected by using a point group measurement device such as the LiDAR, and the wireless communication characteristics are estimated according to the state of the moving object 2 every moment.

### Embodiment 8

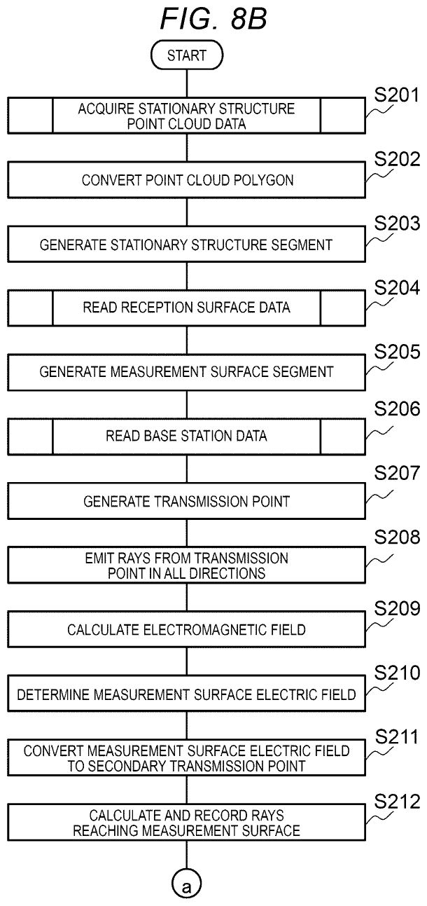

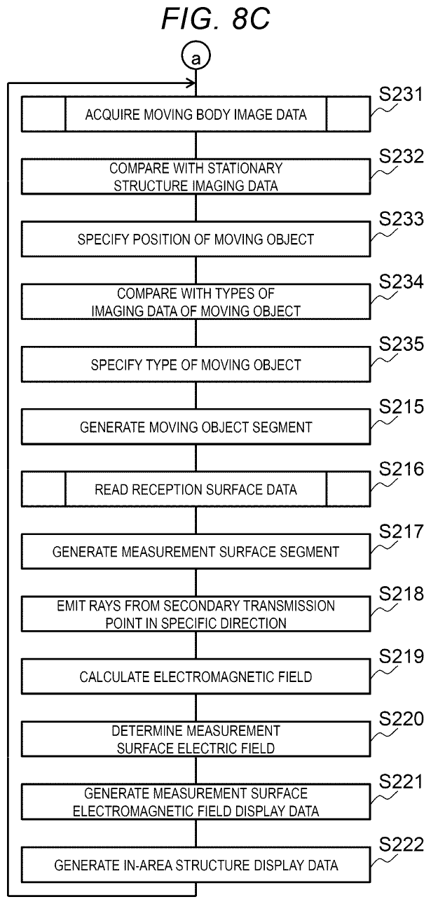

Embodiment 8 of the invention will be described with reference to FIGS. 8a to 8c. In Embodiment 8, differences from Embodiment 7 described above will be mainly described, the same configurations and processing as those in Embodiment 7 will be denoted by the same reference numerals, and descriptions thereof will be omitted.

FIG. 8a is a diagram illustrating another configuration of the wireless environment estimation system 50 according to Embodiment 8.

As main components, the wireless environment estimation system 50 includes the calculation engine 300 which performs electromagnetic field calculation in a service area of the wireless system 101, the electromagnetic field calculation control device 310 which supplies various types of data required by the calculation engine 300 and manages calculation results obtained by the calculation engine 300, the measurement area control device 320 that provides data required by the calculation engine 300 for calculation, a video analysis device 360 that provides the data required by the calculation engine 300 for calculation, the structure data generation device 340 that generates structure data, and the output control device 350 that outputs various trial results using a digital twin to an outside. Next, operations of each component will be described in detail.

First, the electromagnetic field calculation control device 310 includes the secondary transmission point generation device 311, the moving object polygon generation device 312, the structure polygon generation device 313, and the reception polygon generation device 314. The reception polygon generation device 314 determines the measurement surface 4 by using the data transmitted from the measurement area control device 320, generates reception polygons serving as the minute segments 14 forming the determined measurement surface 4, and outputs the reception polygons to the calculation engine 300. The structure polygon generation device 313 generates reception polygons serving as the minute segments 12 related to the stationary structure 1 by using the data transmitted from the structure data generation device 340, and outputs the reception polygons to the calculation engine 300. The moving object polygon generation device 312 generates reception polygons serving as the minute segments 13 related to the moving object 2 by using the data transmitted from the video analysis device 360, and outputs the reception polygons to the calculation engine 300. The secondary transmission point generation device 311 generates a secondary transmission point by using a result of the electromagnetic field calculation by the calculation engine 300, and outputs the secondary transmission point to the calculation engine 300.

Secondly, the measurement area control device 320 includes the reception area generation device 321 and the transmission point generation device 322, and outputs data related to a reception surface and the transmission point 19. The reception area generation device 321 acquires, from the reception area input device 329, information about a region for which the wireless communication quality is analyzed in the wireless digital twin, and outputs the information to the reception area generation device 321. The transmission point generation device 322 acquires information about an emission point of the ray 11 in the electromagnetic field calculation from the base station position input device 328, and outputs the information to the transmission point generation device 322.

Third, the video analysis device 360 includes a structure database 361, a structure model database 362, a video determination device 363, a model data generation device 364, and a video storage device 365. The video storage device 365 acquires an output of a video-capturing device 369 that acquires the structure data of the moving object 2 in the service area of the wireless system 101 as a video, stores the acquired data, and outputs the data to the video determination device 363. The structure database 361 stores in advance images of various moving objects 2 and images related to stationary structures in the wireless service area. The structure model database 362 stores information in which various images of the moving object 2 are associated with shape data. The video determination device 363 determines the position, the movement direction, and the movement speed of the moving object 2 by using the information stored in the video storage device 365 and the information stored in the structure database 361, and transmits the determined position, movement direction, and movement speed of the moving object 2 to the model data generation device 364. The model data generation device 364 generates a planar segment representing the moving object 2 in a cyberspace by using the information stored in the structure model database 362, and outputs information about the generated planar segment to an outside of the video analysis device 360.

Fourth, the structure data generation device 340 includes the structure database 341, the surface correction device 342, the point group and surface conversion device 343, the point group storage device 344, and the model data generation device 345. The point group storage device 344 acquires the structure data of the stationary structure 1 in the service area of the wireless system 101 as a point group from the point group data acquisition device 348, stores the acquired data, and outputs the data to the point group and surface conversion device 343. The point group and surface conversion device 343 converts the input point group into a planar segment and outputs the planar segment to the surface correction device 342. The surface correction device 342 checks a connection state of the planar segment output from the point group and surface conversion device 343, corrects a defect, and outputs information about the planar segment to the structure database 341. Data related to a structure present in the service area may be generated from a point group obtained by actual measurement, or may be output to the structure data generation device 340 by the structure data input device 349. The model data generation device 345 outputs the data related to the structure output from the structure data input device 349 and the data related to the structure read from the structure database 341 to an outside of the structure data generation device 340.

Fifth, the output control device 350 includes the electric field intensity data storage device 351, the structure and moving object data storage device 352, and the display data generation device 353. The electric field intensity data storage device 351 acquires an electromagnetic field analysis result from the calculation engine 300. The structure and moving object data storage device 352 acquires, from the calculation engine 300, data related to the stationary structure 1 and the moving object 2 used by the calculation engine 300 for the for the electromagnetic field calculation. The display data generation device 353 generates image data representing the electromagnetic field intensity by using the data acquired by the electric field intensity data storage device 351 and the data acquired by the structure and moving object data storage device 352, and outputs the image data to a display device 359.

FIGS. 8b and 8c are flowcharts of processing in which the wireless environment estimation system 50 according to Embodiment 8 generates a wireless digital twin.

Steps S201 to S212 are the same as those in Embodiment 7 (FIG. 7b) described above. After step S212, the wireless environment estimation system 50 acquires image data of the moving object 2 (S231), compares the acquired image with an image of a structure in the service area of the wireless system 101 stored in the structure database 341 in advance (S232), and specifies a position of the moving object 2 (S233). The wireless environment estimation system 50 compares the images of the various moving objects 2 stored in the structure database 361 in advance with the acquired image (S234), and specifies the shape associated with the type of the moving object 2 (S235). Thereafter, the wireless environment estimation system 50 generates the minute segment 13 in which the rays 11 related to the moving object 2 interact based on the specified position and shape of the moving object 2 (S215). Subsequent steps S216 to S222 are the same as those in Embodiment 7 (FIG. 7c) described above.

According to the present embodiment, there is an effect in implementing the wireless digital twin in which the movement of the moving object 2 in the wireless communication area including the three-dimensionally traveling object is detected by using an image-capturing device such as a camera which is less expensive than the point group measuring device such as the LiDAR, and the wireless communication characteristics are estimated according to the state of the moving object 2 every moment.

### Embodiment 9

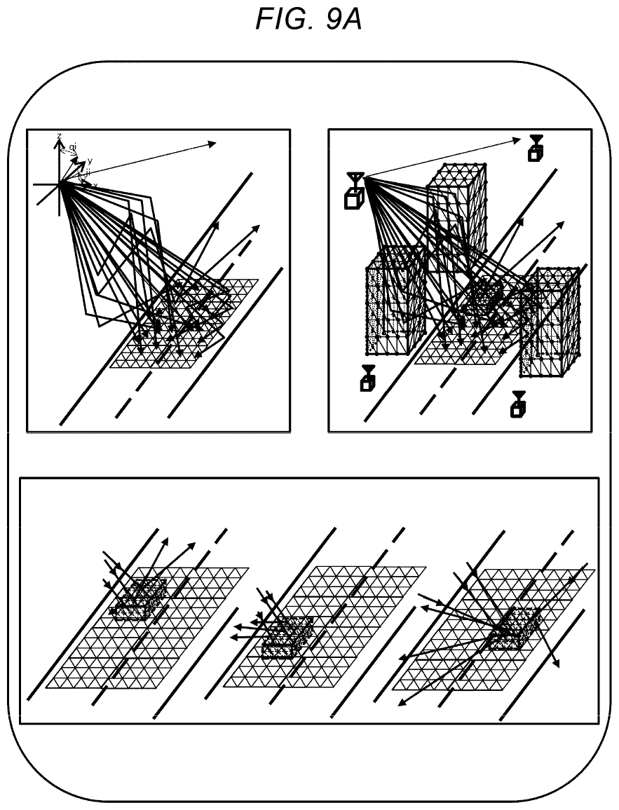

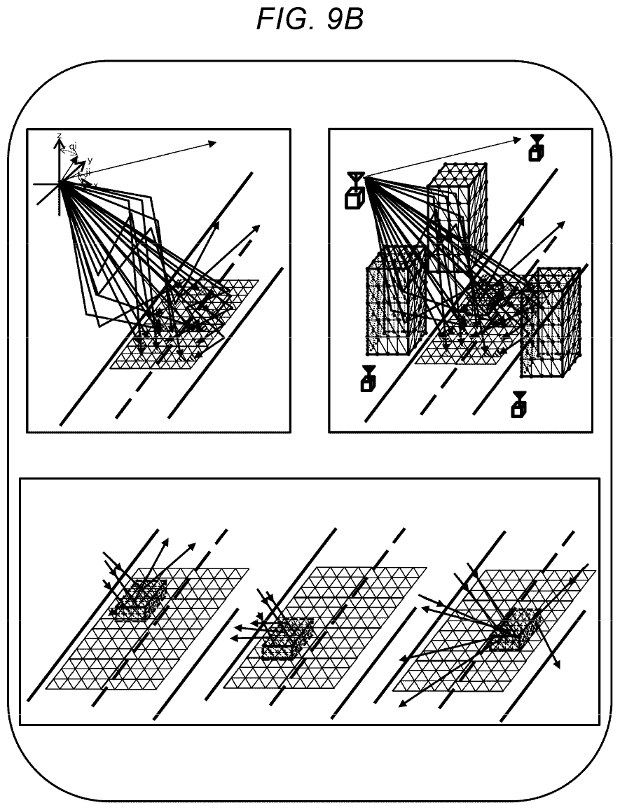

Embodiment 9 of the invention will be described with reference to FIGS. 9a and 9b. In Embodiment 9, differences from Embodiment 1 described above will be mainly described, the same configurations and processing as those in Embodiment 1 will be denoted by the same reference numerals, and descriptions thereof will be omitted.

FIG. 9a is a diagram illustrating a display example of a prediction result of an electromagnetic field distribution according to Embodiment 9, and illustrates a display example of an estimation result a prediction result of an and electromagnetic field distribution in a service area of the wireless system 101 in a wireless digital twin by the wireless environment estimation system 50. FIG. 9b is a diagram illustrating a display example in which the minute segment 16 that does not serve as a secondary transmission point is omitted.

In the wireless digital twin according to Embodiment 9, an influence of the stationary structure 1 and an influence of the moving object 2 on the electromagnetic field distribution in the service area can be individually displayed. For example, as illustrated on the upper left side of FIGS. 9a and 9b, the electromagnetic field distribution obtained by the electromagnetic field analysis, that is, the ray 11 emitted from the base station 5 and the ray 21 emitted from the minute segment 12 can be displayed. In particular, as illustrated in the lower parts of FIGS. 9a and 9b, a variation in the electromagnetic field distribution in the service area caused by the moving object 2 is displayed at a high speed according to changes in the position and the posture of the moving object 2. In the wireless digital twin according to Embodiment 9, data of a stationary structure in the service area is stored in advance, and structure data of the moving object 2 can be acquired in real time by the LiDAR 7 and/or the camera 8. Therefore, as illustrated on the upper right side of FIGS. 9a and 9b, these structure data can be displayed superimposed on the electromagnetic field distribution obtained by the electromagnetic field analysis. By simultaneously displaying actual conditions of the stationary structure 1 and the moving object 2 in an actual space and the electromagnetic field actually present as energy in the space, it is possible to speed up and effectively formulate plans for stable operation of the wireless system 101 and to formulate responses to changes in the operating status. This is particularly effective when the moving object 2, whose behavior is generally difficult to specify, becomes an obstacle to planning stable operations and formulating responses to changes.

According to the present embodiment, the observed position of the moving object 2 is input to the wireless environment estimation system 50 and the digital twin, the wireless communication quality of the moving object 2 in a controlling area is estimated, and the moving object 2 can be operated stably and safely.

### Embodiment 10

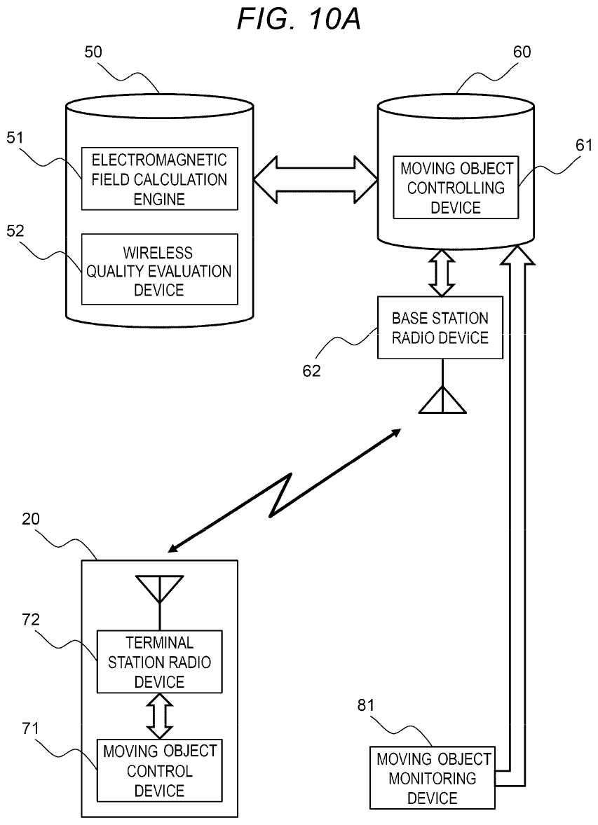

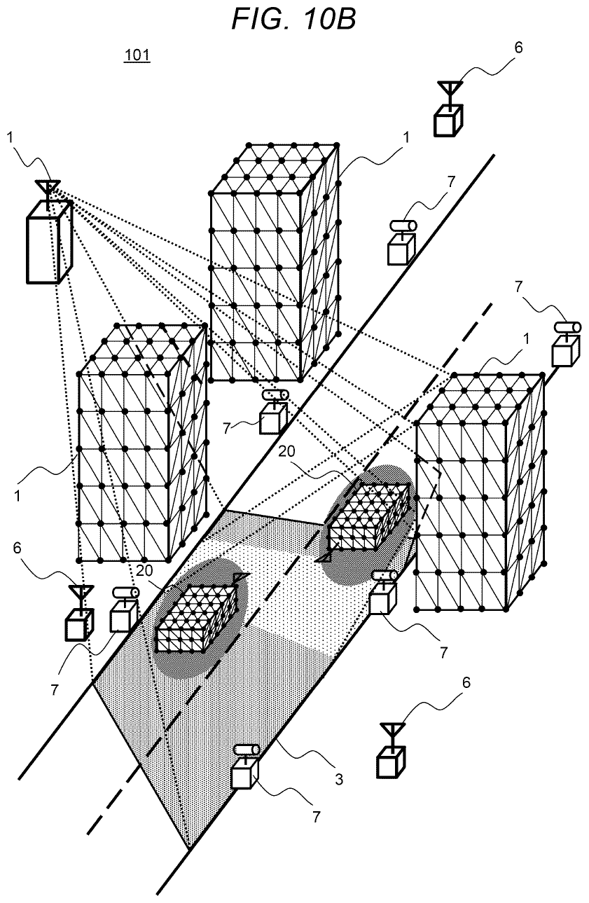

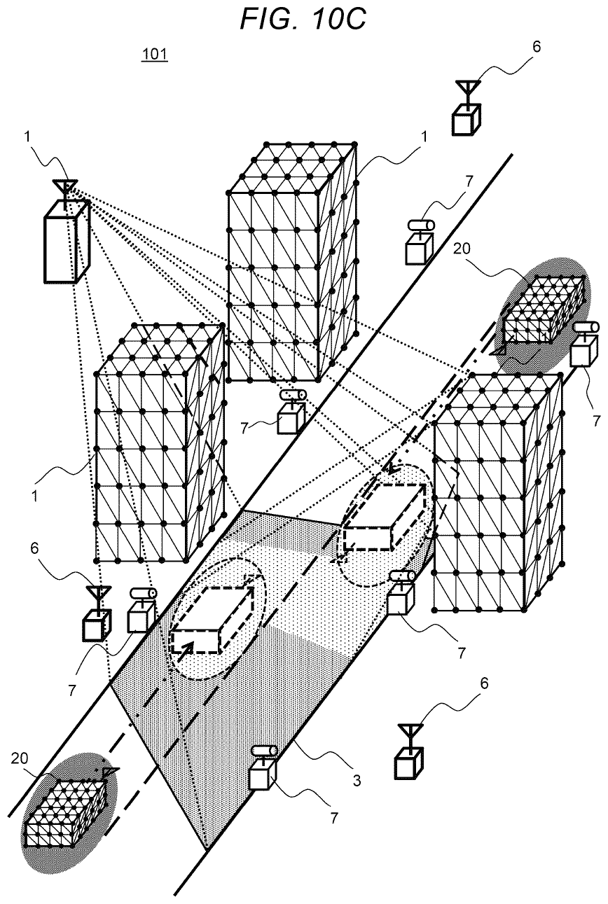

Embodiment 10 of the invention will be described with reference to FIGS. 10a to 10c. In Embodiment 10, differences from Embodiment 1 described above will be mainly described, the same configurations and processing as those in Embodiment 1 will be denoted by the same reference numerals, and descriptions thereof will be omitted.

FIG. 10a is a diagram illustrating a configuration example of an operation monitoring control system using a wireless digital twin according to Embodiment 10.

The operation monitoring control system according to Embodiment 10 includes a moving object controlling server 60, the wireless environment estimation system 50 including an electromagnetic field analysis server, a moving object control device 71, and a moving object monitoring device 81 as main components.

A moving object controlling device 61 of the moving object controlling server 60 manages operations of the moving object 2 in a moving object controlling area. The moving object 20 is equipped with the moving object control device 71. The moving object control device 71 wirelessly transmits an operation state signal of the moving object 20 to the moving object controlling device 61 via a terminal station radio device 72 and a base station radio device 62 connected to the moving object controlling server 60. The moving object monitoring device 81 acquires a position and a posture of the moving object 20 in an actual space from devices such as the LiDAR 7 and the camera 8, and transmits information about the acquired position and posture to the moving object controlling server 60.

The moving object controlling server 60 transmits the information about the position and posture of the moving object 20 acquired from the moving object monitoring device 81 to the wireless environment estimation system 50. In the wireless environment estimation system 50, an electromagnetic field calculation engine 51 calculates an electromagnetic field distribution in a moving object controlling area in the information about the position and posture of the moving object 20 received from the moving object controlling server 60, and a wireless quality evaluation device 52 estimates the wireless communication quality by using a calculation result of the electromagnetic field distribution and transmits the estimated wireless communication quality to the moving object controlling server 60.

The moving object controlling device 61 of the moving object controlling server 60 formulates a control plan for the moving object 20 to operate stably and safely based on the current wireless communication quality of the moving object 20 acquired from the wireless environment estimation system 50 and a predicted value of a future wireless communication quality. The base station radio device 62 transmits the developed management plan to the terminal station radio device 72 via the moving object control device 71.

FIG. 10b is a diagram illustrating a currently estimated state of the wireless communication quality of the wireless system 101 grasped by the moving object controlling server 60. Dark grey areas in the drawing indicate areas where the electric field is weak, and light grey areas indicate areas where the electric field is somewhat weak. Both of the two moving objects 20 in the drawing are located in areas where the electric field is somewhat weak, and some measure is required in the control to deal with the instability of a wireless communication line. FIG. 10c is a diagram illustrating a future predicted state of the wireless communication quality of the wireless system 101 that is predicted by the moving object controlling server 60. As in FIG. 10b, dark grey areas in the drawing indicate areas where the electric field is weak, and light grey areas indicate areas where the electric field is somewhat weak in FIG. 10c. Both of the two moving objects 20 in the drawing are currently in a region where good wireless communication quality is obtained, but may enter a region where wireless communication is difficult at a future time point. In the control, it is necessary to notify the moving object 20 in advance of a possibility of a wireless communication line being cut off, and to plan some kind of action to deal with the cut-off of the wireless communication line. According to the present embodiment, in the remote control of the moving object 20 using wireless communication, the current and future quality of the wireless communication line can be predicted, and a control plan for implementing a safe and stable operation of the moving object 20 can be created, which is effective in the stable and safe operation of the transportation system.

### Embodiment 11

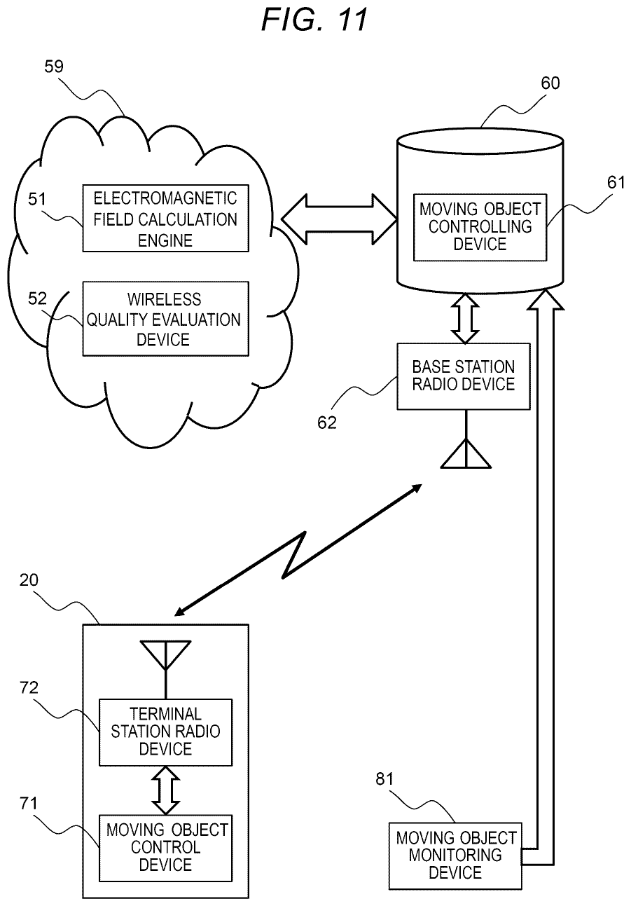

Embodiment 11 of the invention will be described with reference to FIG. 11. In Embodiment 11, differences from Embodiment 10 described above will be mainly described, the same configurations and processing as those in Embodiment 10 will be denoted by the same reference numerals, and descriptions thereof will be omitted.

FIG. 11 is a diagram illustrating another configuration example of an operation monitoring control system using a wireless digital twin according to Embodiment 11. Embodiment 11 is different from Embodiment 10 described above in that an electromagnetic field analysis cloud 59 is provided instead of the wireless environment estimation system 50.

The operation monitoring control system according to Embodiment 11 includes the moving object controlling server 60, the electromagnetic field analysis cloud 59, the moving object control device 71, and the moving object monitoring device 81 as main components.

The electromagnetic field analysis cloud 59 executes electromagnetic field analysis processing executed by the wireless environment estimation system 50 according to Embodiment 10 on a virtual computer constructed on a plurality of physical computer resources.

According to the present embodiment, in the remote control of the moving object 20 using wireless communication, the current and future quality of the wireless communication line can be predicted, and a control plan for implementing a safe and stable operation of the moving object 20 can be created, which is effective in the stable and safe operation of the transportation system. Furthermore, there is an effect of enabling moving object control services to be expanded over a wide area.

The invention is not limited to the embodiments described above and includes various modifications and equivalent configurations within the scope of the appended claims. For example, the embodiments described above are described in detail for easy understanding of the invention, and the invention is not necessarily limited to those including all the configurations described above. A part of a configuration of one embodiment may be replaced with a configuration of another embodiment. A configuration of one embodiment may also be added to a configuration of another embodiment. Another configuration may be added to, deleted from, or replaced with a part of the configuration of each embodiment.

A part or all of the configurations, functions, processing units, processing methods, and the like described above may be implemented by hardware by, for example, designing with an integrated circuit, or may be implemented by software by, for example, a processor interpreting and executing a program for implementing each function.

Information such as a program, a table, and a file for implementing each function can be stored in a storage device such as a memory, a hard disk, or a solid state drive (SSD), or can be stored in a recording medium such as an IC card, an SD card, or a DVD.

Control lines and information lines considered to be necessary for descriptions are shown, and not all control lines and information lines necessary for implementation are shown. Actually, it may be considered that almost all the configurations are connected.

What is claimed is:

1. A wireless environment estimation system comprising:
a computer including an arithmetic device configured to execute predetermined processing and a storage device connected to the arithmetic device, wherein
the storage device stores stationary structure data including structure data of a stationary structure in a wireless communication area, moving object data including structure data of a moving object in the wireless communication area, and observation region data related to an observation region of an electromagnetic field, and
the arithmetic device
uses the stationary structure data and the observation region data to generate a first electromagnetic field analysis model for analyzing an electromagnetic wave reflected by the stationary structure in the observation region,
sets a primary wave source at a position of a wireless station,
generates a secondary transmission point from an electromagnetic field that is obtained by calculation using the first electromagnetic field analysis model and that reaches the observation region,
uses the moving object data and the observation region data to generate a second electromagnetic field analysis model for analyzing an electromagnetic wave emitted from the secondary transmission point, and
uses the second electromagnetic field analysis model to calculate an electromagnetic field caused by an electromagnetic wave emitted in a direction opposite to that of an electromagnetic wave reaching the secondary transmission point.

2. The wireless environment estimation system according to claim 1, wherein
the observation region is a surface.

3. The wireless environment estimation system according to claim 1, wherein
the observation region is a measurement shell having a volume.

4. The wireless environment estimation system according to claim 1, wherein
the observation region is set in a region where the moving object is present.

5. The wireless environment estimation system according to claim 1, wherein
the structure data of the moving object is implemented by a polygon derived from a point group measured by LiDAR.

6. The wireless environment estimation system according to claim 1, wherein
the storage device stores reference image data and the structure data of the moving object, and
the structure data of the moving object is structure data associated with the reference image data similar to image data captured by a camera.

7. The wireless environment estimation system according to claim 5, wherein
the arithmetic device
uses a movement direction and a movement speed of the moving object derived from measurement results of the LiDAR at a plurality of time points to estimate a position of the moving object after a predetermined time, and
uses the estimated position of the moving object to calculate an electromagnetic field after the predetermined time.

8. The wireless environment estimation system according to claim 6, wherein
a movement direction and a movement speed of the moving object derived from image data captured by the camera at a plurality of time points are used to estimate a position of the moving object after a predetermined time, and
the estimated position of the moving object is used to calculate an electromagnetic field after the predetermined time.

9. The wireless environment estimation system according to claim 1, wherein
a surface of the stationary structure on which an electromagnetic wave is to be observed and a surface of the moving object on which an electromagnetic wave is to be observed are divided to generate minute surface segments, and
a ray tracing method is used to calculate an interaction between the generated minute surface segment and a ray simulating the electromagnetic wave to derive an electromagnetic field.

10. The wireless environment estimation system according to claim 1, further comprising:
an electromagnetic field calculation engine configured to calculate an electromagnetic field caused by an electromagnetic wave in the wireless communication area;
an electromagnetic field calculation control device configured to generate data used by the electromagnetic field calculation engine to calculate the electromagnetic field;
a structure data generation device configured to generate the stationary structure data;
a moving object data generation device configured to generate the moving object data;
a measurement region control device configured to generate the observation region data; and
an output control device configured to output a calculation result of the electromagnetic field, wherein
the electromagnetic field calculation control device divides surfaces of the stationary structure, the moving object, and the observation region of the electromagnetic field used by the electromagnetic field calculation engine to calculate the electromagnetic field, to generate segments based on the stationary structure data output from the structure data generation device, the moving object data output from the moving object data generation device, and the observation region data output from the measurement region control device, and the electromagnetic field calculation engine uses the generated segments to calculate the electromagnetic field.

11. The wireless environment estimation system according to claim 10, wherein
the measurement region control device receives an input of a position of a base station and an input of an electromagnetic wave characteristic measurement area in a wireless communication service area, and
the output control device outputs data representing an electromagnetic field in the electromagnetic wave characteristic measurement area.

12. The wireless environment estimation system according to claim 11, wherein
the output control device outputs data representing a radio wave propagating in the electromagnetic wave characteristic measurement area as a ray.

13. The wireless environment estimation system according to claim 12, wherein
a position and a shape of the stationary structure in the wireless communication service area and a position and a shape of the moving object in the wireless communication service area are displayed together with a ray propagating in the electromagnetic wave characteristic measurement area.

14. A wireless environment estimation method configured to be executed by a wireless environment estimation system,
the wireless environment estimation system including a computer including an arithmetic device configured to execute predetermined processing and a storage device connected to the arithmetic device,
the storage device storing stationary structure data including structure data of a stationary structure in a wireless communication area, moving object data including structure data of a moving object in the wireless communication area, and observation region data related to an observation region of an electromagnetic field,
the wireless environment estimation method comprising:
using, by the arithmetic device, the stationary structure data and the observation region data to generate a first electromagnetic field analysis model for analyzing an electromagnetic wave reflected by the stationary structure in the observation region;
setting, by the arithmetic device, a primary wave source at a position of a wireless station;
generating, by the arithmetic device, a secondary transmission point from an electromagnetic field that is obtained by calculation using the first electromagnetic field analysis model and that reaches the observation region;
using, by the arithmetic device, the moving object data and the observation region data to generate a second electromagnetic field analysis model for analyzing an electromagnetic wave emitted from the secondary transmission point; and
using, by the arithmetic device, the second electromagnetic field analysis model to calculate an electromagnetic field caused by an electromagnetic wave emitted in a direction opposite to that of an electromagnetic wave reaching the secondary transmission point.
